(19) United States
(12) Patent Application Publication
(10) Pub. No.: US 2026/0190714 A1
(43) Pub. Date: Jul. 2, 2026

(54) DISPLAY DEVICE

(71) Applicant: LG Display Co., Ltd., Seoul (KR)

(72) Inventors: Myeongsu KIM, Paju-si (KR); Seyong LEE, Paju-si (KR)

(73) Assignee: LG Display Co., Ltd., Seoul (KR)

(21) Appl. No.: 19/432,575

(22) Filed: Dec. 24, 2025

(30) Foreign Application Priority Data
Dec. 30, 2024 (KR) 10-2024-0199613

(51) Int. Cl. H10K 59/131; H10K 59/121

(52) U.S. Cl. CPC H10K 59/131; H10K 59/1213

(57) ABSTRACT

A display device can have a lower voltage line positioned in a display area and arranged in a first mesh pattern, an upper voltage line electrically connected to a common electrode through a contact hole of a second insulating layer, and an upper voltage line positioned in the display area and arranged in a second mesh pattern or a plate pattern, thereby reducing the bezel size of the display device.

### CROSS-REFERENCE TO RELATED APPLICATION

This application claims priority to Korean Patent Application No. 10-2024-0199613, filed in the Republic of Korea on Dec. 30, 2024, which is hereby expressly incorporated by reference for all purposes as if fully set forth herein.

### BACKGROUND

### Field

The present disclosure relates to a display device.

### Discussion of the Related Art

With the advancement of the information society, the demand for display devices for displaying images has been increasing in various forms. Recently, various types of display devices, such as liquid crystal display (LCD) devices and organic light-emitting display (OLED) devices, have been widely utilized.

A display device can include a display panel. The display panel can include a display area, where images are displayed, and a non-display area located outside the display area. The non-display area can be referred to as a “bezel” or a bezel area. A thick bezel can cause inconvenience to users and can be aesthetically not pleasing to the users.

### SUMMARY OF THE DISCLOSURE

The embodiments of the present disclosure can provide a display device capable of reducing a bezel size by arranging voltage lines in the display area.

The embodiments of the present disclosure can provide a display device capable of simplifying the circuit layout in the non-display area by arranging voltage lines in the display area.

The embodiments of the present disclosure can provide a display device capable of reducing a voltage drop by patterning the voltage lines in a specific manner.

The embodiments of the present disclosure can provide a display device capable of reducing the influence of external light on the thin-film transistor (TFT) by patterning the voltage lines in a specific manner.

The embodiments of the present disclosure can provide a display device capable of operating at low power by reducing a voltage drop and protecting the thin-film transistor from external light.

The objects of the embodiments of the present disclosure are not limited to those described herein, and additional objects not explicitly mentioned will be apparent to those skilled in the art from the following description.

The embodiments of the present disclosure can provide a display device comprising a substrate including a display area and a non-display area outside the display area; a lower voltage line disposed on the substrate to supply a first voltage; a first insulating layer disposed on the lower voltage line; an upper voltage line disposed on the first insulating layer to supply a second voltage different from the first voltage; a second insulating layer disposed on the upper voltage line; a pixel electrode disposed on the second insulating layer; a light-emitting layer disposed on the pixel electrode; and a common electrode disposed on the light-emitting layer, wherein the lower voltage line is positioned in the display area and is arranged in a first mesh pattern, wherein the upper voltage line is electrically connected to the common electrode through a contact hole of the second insulating layer, and wherein the upper voltage line is positioned in the display area and is arranged in a second mesh pattern or a plate pattern.

According to the embodiments of the present disclosure, a display device capable of reducing a bezel size can be provided by arranging voltage lines in the display area.

According to the embodiments of the present disclosure, a display device capable of simplifying the circuit layout in the non-display area can be provided by arranging voltage lines in the display area.

According to the embodiments of the present disclosure, a display device capable of reducing voltage drop can be provided by patterning the voltage lines in a specific manner.

According to the embodiments of the present disclosure, a display device capable of reducing the influence of external light on the thin-film transistor can be provided by patterning the voltage lines in a specific manner.

According to the embodiments of the present disclosure, a display device capable of operating at low power can be provided by reducing voltage drop and protecting the thin-film transistor from external light.

The effects of the embodiments of the present disclosure are not limited to those described above, and additional effects not explicitly mentioned will be apparent to those skilled in the art from the claims.

### BRIEF DESCRIPTION OF THE DRAWINGS

The present disclosure will be more fully understood from the following detailed description and the accompanying drawings. The detailed description and drawings are provided for illustrative purposes only and are not intended to limit the scope of the present disclosure.

FIG. 1 is a perspective view of a display device according to embodiments of the present disclosure.

FIG. 2 is a diagram illustrating a structure in which a touch screen panel is embedded in a display panel of a display device according to embodiments of the present disclosure.

FIG. 3 is a diagram illustrating an example of a bending structure and a line structure in a planar structure of a display panel according to embodiments of the present disclosure.

FIG. 4 is a diagram illustrating an example of a cross-sectional structure of a display panel according to embodiments of the present disclosure.

FIG. 5 is a plan view of a display panel including voltage lines according to embodiments of the present disclosure.

FIG. 6 and FIG. 7 are diagrams illustrating voltage lines arranged in a display area and a non-display area of FIG. 5.

FIG. 8 to FIG. 13 are plan views and cross-sectional views illustrating voltage lines arranged in a display area according to embodiments of the present disclosure.

FIG. 14 is a cross-sectional view of a display panel illustrating a display area and a non-display area according to embodiments of the present disclosure.

### DETAILED DESCRIPTION OF THE EMBODIMENTS

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Various embodiments of the present disclosure will be described in detail with reference to the accompanying drawings. All the components of each display device/apparatus according to all embodiments of the present disclosure are operatively coupled and configured.

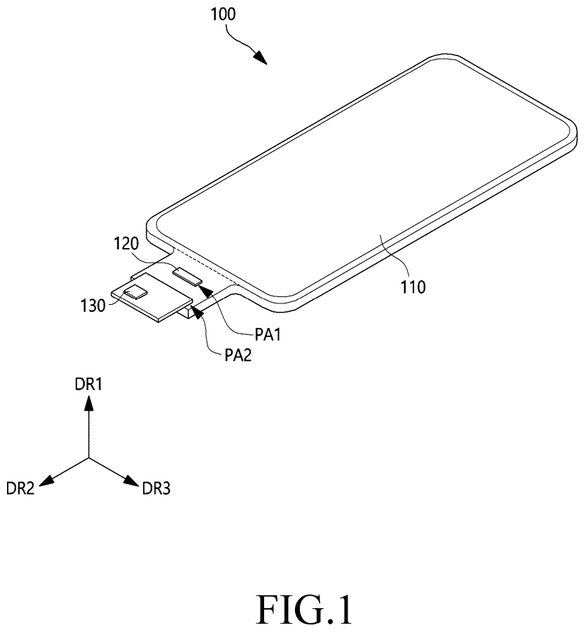

FIG. 1 is a perspective view of a display device 100 according to embodiments of the present disclosure.

Referring to FIG. 1, the display device 100 according to embodiments of the present disclosure can be applied to portable electronic devices such as a mobile phone, smartphone, tablet personal computer (tablet PC), mobile communication terminal, electronic notebook, electronic book, portable multimedia player (PMP), navigation system, and ultra-mobile PC (UMPC).

Alternatively, the display device 100 of the present disclosure can be applied to a television, laptop, monitor, advertisement display, or wearable devices such as a smartwatch or watch phone. The display device 100 can also be applied to a vehicle dashboard, a center fascia of a vehicle, a center information display (CID) arranged on a vehicle dashboard, a room mirror display replacing a side mirror, or a rear-seat entertainment display installed on the back of a front seat.

The display device 100 of the present disclosure can be a display device using an organic light-emitting diode (OLED), a quantum dot (QD) light-emitting display device including a quantum dot light-emitting layer, an inorganic light-emitting display device including an inorganic semiconductor, or a micro light-emitting display device using a micro light-emitting diode (micro-LED). In the following description, the display device 100 is described mainly as an OLED display device as an example; however, the present disclosure is not limited thereto.

The display device 100 according to embodiments of the present disclosure can include a display panel 110 and a display driving circuit as components for image display. The display driving circuit can be a circuit for driving the display panel 110. The display driving circuit can include a data driving circuit, a gate driving circuit, and a controller; however, the embodiments of the present disclosure are not limited thereto.

The display device 100 of the present disclosure can include the display panel 110, first pad area PA1, and second pad area PA2. The first pad area PA1 and the second pad area PA2 can be connected to or bonded (or attached) to a driving circuit such as a data driving circuit or a gate driving circuit.

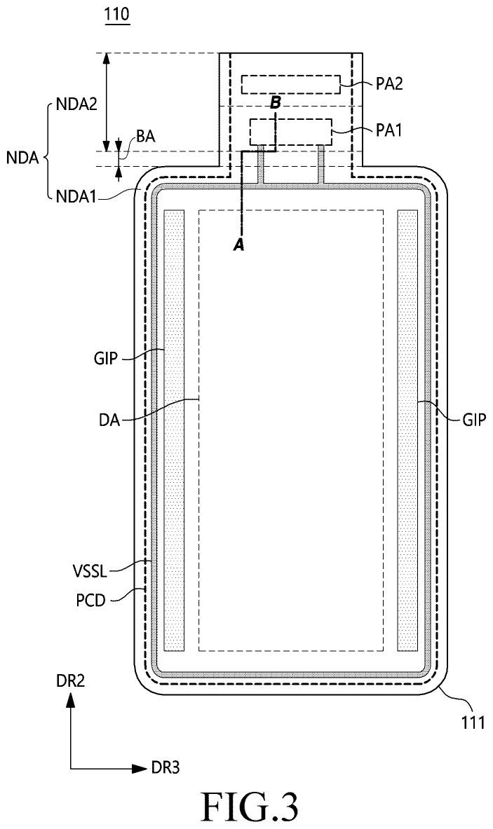

The first pad area PA1 and the second pad area PA2 can be positioned in the display panel 110. Referring to FIG. 1 and FIG. 3, a first driver 120 can be arranged in the first pad area PA1. Referring to FIG. 1 and FIG. 3, one end of a circuit section in which a second driver 130 is arranged can be connected to the second pad area PA2 of the display panel 110.

Although two pad areas PA1, PA2 are shown, the number of pad areas can be two or more. For example, a pad area can be an area located at an edge of a substrate. A pad area can be an area in which a chip is mounted. A pad area can be an area where a pad of another substrate or another film is connected to a pad of the substrate of the display panel 100.

The display panel 110 can have a rectangular planar shape with a short side in a first direction and a long side in a second direction intersecting the first direction. A corner where the short side in a first direction and the long side in a second direction meet can be rounded with a predetermined curvature or can be formed at a right angle. The planar shape of display panel 110 is not limited to a rectangle and can be formed as another polygonal shape, a circular shape, or an elliptical shape. Display panel 110 can be formed as a flat panel; however, the present disclosure is not limited thereto. For example, display panel 110 can include a curved portion formed at the left and right edges, having a fixed or varying curvature. Additionally, display panel 110 can be bendable, flexible, foldable, or rollable, but is not limited thereto.

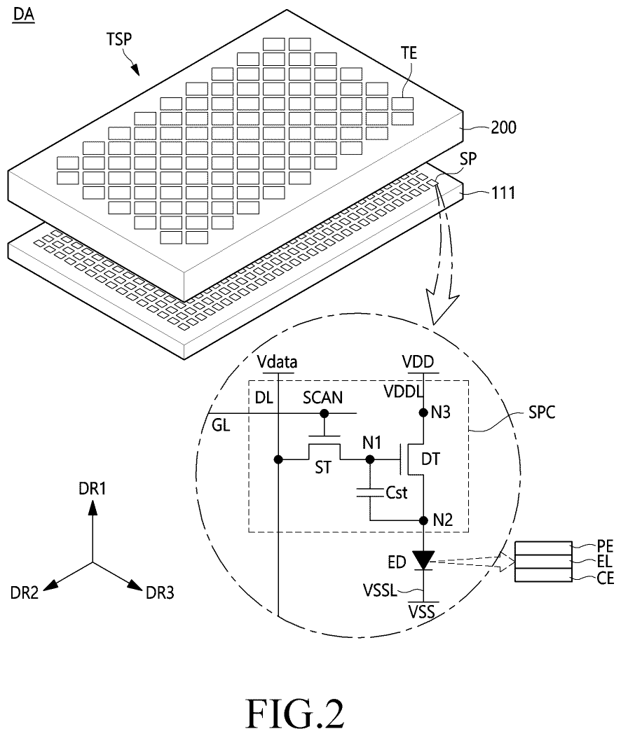

FIG. 2 is a diagram illustrating an example of a structure in which a touch screen panel is embedded in display panel 110 of display device 100 according to embodiments of the present disclosure.

Referring to FIG. 2, the display panel according to embodiments of the present disclosure can include a substrate 111, in which a plurality of sub-pixels SP are arranged, and an encapsulation layer 200 disposed on substrate 111. Encapsulation layer 200 can also be referred to as an encapsulation substrate or an encapsulation portion.

The display device 100 according to embodiments of the present disclosure can be a self-emissive display device; however, the present disclosure is not limited thereto. When display device 100 is a self-emissive display device, each of plurality of sub-pixels SP disposed on substrate 111 can include a light-emitting device ED and a sub-pixel circuit SPC for driving light-emitting device ED.

Each sub-pixel circuit SPC can include a plurality of transistors and at least one capacitor for driving light-emitting device ED; however, the embodiments of the present disclosure are not limited thereto. In the present disclosure, sub-pixel circuit SPC can supply a driving current to light-emitting device ED at a predetermined timing to drive light-emitting element ED. Light-emitting element ED can be driven by the driving current to emit light.

A variety of signal lines for driving plurality of sub-pixels SP can be arranged on substrate 111 of display panel 110. For example, various types of signal lines can include a plurality of data lines DL for transmitting data signals (also referred to as data voltages or image signals) to plurality of sub-pixels SP and a plurality of gate lines GL for transmitting gate signals (also referred to as scan signals) to plurality of sub-pixels SP.

For example, plurality of data lines DL and plurality of gate lines GL can intersect each other. Each of plurality of gate lines GL can be arranged to extend in a first direction (e.g., a row direction or a column direction). Each of plurality of data lines DL can be arranged to extend in a second direction different from the first direction (e.g., a column direction or a row direction).

In some embodiments of the present disclosure, the first direction can be a row direction, and the second direction can be a column direction. In other embodiments, the first direction can be a column direction, and the second direction can be a row direction. The row direction and the column direction can be relative directions. For example, the column direction can be regarded as the row direction depending on the viewing perspective, and vice versa. For convenience of description, plurality of data lines DL are arranged in the column direction, and plurality of gate lines GL are arranged in the row direction in the following description. However, the embodiments of the present disclosure are not limited thereto. The angle formed between the first direction and the second direction can be perpendicular (e.g., 90 degrees) or can have an angle different from 90 degrees.

The sub-pixel circuit SPC can be controlled by a data driving circuit. The data driving circuit can be a circuit for driving plurality of data lines DL and can output data signals to plurality of data lines DL. The data driving circuit can receive digital image data from a controller, convert the received image data into an analog data signal (also referred to as a data voltage), and output the analog data signal to plurality of data lines DL. The data driving circuit can be connected to an outer edge of a display area of display panel 110. In another embodiment, the data driving circuit can be disposed in

The sub-pixel circuit SPC can be controlled by a gate driving circuit. The gate driving circuit is a circuit for driving plurality of gate lines GL and can output gate signals to plurality of gate lines GL. The gate driving circuit receives a first gate voltage, corresponding to a turn-on voltage (also referred to as a turn-on level voltage), and a second gate voltage, corresponding to a turn-off voltage (also referred to as a turn-off level voltage), along with various gate control signals GCS. Then, the gate driving circuit can generate gate signals that include a period in which the first gate voltage is applied and a period in which the second gate voltage is applied for a predetermined period (e.g., one frame period) and can supply the generated gate signals to plurality of gate lines GL. In one example, the turn-on level voltage can be a high-level voltage, and the turn-off level voltage can be a low-level voltage. In another example, the turn-on level voltage can be a low-level voltage, and the turn-off level voltage can be a high-level voltage.

In the display device 100 according to embodiments of the present disclosure, the gate driving circuit can be embedded in display panel 110 as a gate-in-panel GIP type circuit; however, the present disclosure is not limited thereto. For example, the gate driving circuit can be arranged as a GIP type circuit, as illustrated in FIG. 3.

When the gate driving circuit is disposed in display area DA of display panel 110, the gate driving circuit can overlap sub-pixels SP disposed in display area DA in a vertical direction. For example, the gate driving circuit can vertically overlap light-emitting devices and transistors included in sub-pixels SP disposed in display area DA. The gate driving circuit can include a plurality of transistors.

Each of the plurality of transistors included in the gate driving circuit can include an active layer comprising a first semiconductor material, and each of the plurality of transistors included in sub-pixels SP can include an active layer comprising a second semiconductor material. In one example, the first semiconductor material and the second semiconductor material can be substantially the same. In another example, the first semiconductor material and the second semiconductor material can be different. For example, the first semiconductor material can be a silicon-based semiconductor material (e.g., low-temperature polycrystalline silicon LTPS), and the second semiconductor material can be an oxide semiconductor material. For example, the active layer can be a semiconductor layer but is not limited thereto.

A controller is a device for controlling the data driving circuit and the gate driving circuit and can control the driving timings of plurality of data lines DL and plurality of gate lines GL. The controller can receive input image data from a host system and can supply image data to the data driving circuit based on the received input image data. The controller can be implemented as a separate component from the data driving circuit or can be integrated with the data driving circuit as an integrated circuit IC. The controller can be a timing controller used in display technology or a control device that includes a timing controller and performs additional control functions. Alternatively, the controller can be a control device separate from the timing controller or a circuit inside a control device.

The plurality of transistors can include a driving transistor DT for driving light-emitting device ED and a scan transistor ST that turns on or off in response to a scan signal SCAN.

The driving transistor DT can supply a driving current to light-emitting device ED. Scan transistor ST can be configured to control the electrical state of a corresponding node in sub-pixel circuit SPC or to control the state or operation of driving transistor DT. At least one capacitor can include a storage capacitor Cst, which maintains a constant voltage during a frame period.

For driving the sub-pixel SP, a data signal Vdata, which is an image signal, and a scan signal SCAN, which is a type of gate signal, can be applied to the sub-pixel SP. In addition, for driving the sub-pixel SP, a common driving signal including a driving voltage VDD and a reference voltage VSS can be applied to the sub-pixel SP. The light-emitting device ED can include a pixel electrode PE, an intermediate layer EL, and a common electrode CE. The intermediate layer EL can be disposed between the pixel electrode PE and the common electrode CE and can be defined as an emission layer. For example, the pixel electrode PE can be an electrode disposed in each sub-pixel SP, and the common electrode CE can be an electrode commonly disposed in a plurality of sub-pixels SP. In one example, the pixel electrode PE is an anode, and the common electrode CE is a cathode. For example, the common electrode CE can be electrically connected to the reference voltage line VSSL. A reference voltage VSS, which is a type of common voltage, can be applied to the common electrode CE through the reference voltage line VSSL. The pixel electrode PE can be electrically connected to the second node N2 of the driving transistor DT of each sub-pixel SP either directly or indirectly through another transistor. The driving transistor DT can be a transistor for supplying a driving current to light-emitting device ED. Driving transistor DT can be connected between the driving voltage line VDDL and the light-emitting device ED.

The driving transistor DT can be a driving transistor for supplying a driving current to the light-emitting device ED. The driving transistor DT can be connected between the driving voltage line VDDL and the light-emitting device ED.

The driving transistor DT can include a first node N1, a second node N2, and a third node N3. The first node N1 can receive a data signal Vdata. The second node N2 can be electrically connected to the light-emitting device ED. The third node N3 can receive a driving voltage VDD, which is another type of common voltage, from the driving voltage line VDDL. The driving transistor DT can be connected on the second node N2 and the third node N3. In this disclosure, the driving voltage VDD can also be referred to as the second common voltage, a high-potential power supply voltage, or a high-potential voltage. The driving voltage line VDDL can also be referred to as the second common voltage line, a low-potential power supply voltage line, or a low-potential voltage line.

In the driving transistor DT, the first node N1 can be a gate node, the second node N2 can be a source node or a drain node, and the third node N3 can be a drain node or a source node. Hereinafter, for convenience of explanation, in the driving transistor (DT), the first node (N1) can be a gate node, the second node (N2) can be a source node, and the third node (N3) can be a drain node. However, the embodiments of this disclosure are not limited thereto.

The scan transistor ST, included in the sub-pixel circuit SPC illustrated in FIG. 2, can be a switching transistor that transmits a data signal Vdata, which is an image signal, to the second node N2, which is the gate node of the driving transistor DT. The scan transistor ST is controlled to turn on and off by a scan signal SCAN, which is a type of gate signal applied through a scan line GL, a type of gate line GL. This allows control of the electrical connection between the second node N2 of the driving transistor DT and the data line DL.

The storage capacitor Cst can be electrically connected between the first node N1 and the second node N2 of the driving transistor DT. The storage capacitor Cst can include at least one capacitor electrode that is either electrically connected to or corresponds to the first node N1 of the driving transistor DT. It can also include at least one capacitor electrode that is either electrically connected to or corresponds to the second node N2 of the driving transistor DT.

Each of the driving transistor DT and the scan transistor ST can be either an n-type transistor or a p-type transistor. However, the embodiments of this disclosure are not limited thereto. For example, one of the driving transistor DT and the scan transistor ST can be either an n-type transistor or a p-type transistor.

As illustrated in FIG. 2, the sub-pixel circuit SPC can have a 2T1C (2-transistor, 1-capacitor) structure, including two transistors DT and ST and one capacitor Cst. Depending on the case, it can include one or more additional transistors or one or more additional capacitors. For example, the sub-pixel circuit SPC can have a 3T1C structure, including three transistors and one capacitor. In another example, the sub-pixel circuit SPC can have an 8T1C structure, including eight transistors and one capacitor. In yet another example, the sub-pixel circuit SPC can have a 6T2C structure, including six transistors and two capacitors. In yet another example, the sub-pixel circuit SPC can have a 7T1C structure, including seven transistors and one capacitor. The embodiments of this disclosure are not limited thereto. Depending on the structure of the sub-pixel circuit SPC, the type and number of gate lines supplying the gate signal to the sub-pixel SP can vary. Additionally, depending on the structure of the sub-pixel circuit SPC, the type and number of common driving signals supplied to the sub-pixel SP can also vary.

Since the circuit elements within each sub-pixel SP (e.g., the light-emitting device ED implemented as an organic light-emitting diode OLED containing an organic material) are vulnerable to external moisture and oxygen, an encapsulation layer 200 can be disposed on the display panel 110. The encapsulation layer 200 can prevent external moisture or oxygen from penetrating the circuit elements (e.g., the light-emitting device ED).

The display device 100 according to the embodiments of this disclosure can include a touch screen panel TSP formed on the encapsulation layer 200 and embedded in the display panel 110 to provide a touch-sensing function. For example, in the display device 100, a plurality of touch electrodes TE forming the touch screen panel TSP can be disposed on the encapsulation layer 200, thereby constituting the display panel 110.

The display device 100 according to the embodiments of this disclosure can provide not only an image display function but also a touch-sensing function that detects whether a touch has occurred due to a touch object such as a finger or a pen and determines the touch position.

For example, if the encapsulation layer 200 consists of multiple layers, a touch electrode TE can be disposed between a first encapsulation layer and a second encapsulation layer. However, the present disclosure is not limited thereto.

The display device 100 can use a capacitance-based touch sensing method, such as a mutual-capacitance method or a self-capacitance method, to detect touch.

FIG. 3 is a diagram illustrating an example of the bending structure and line structure in the planar structure of the display panel 110 according to embodiments of the present disclosure.

Referring to FIG. 3, the substrate 111 of the display panel 110 according to embodiments of the present disclosure can include the display area DA and the non-display area NDA. The display area DA and the non-display area NDA can also be referred to as regions of the display panel 110.

All lines and electrodes are formed on the substrate 111. In the display device 100 according to embodiments of the present disclosure, the substrate 111 can be a flexible substrate capable of bending. In the present disclosure, “bending” can have the same meaning as “folding” or “flexible.”

The non-display area NDA is a region where an image is not displayed and can refer to the area excluding the display area DA. No sub-pixel SP is arranged in the non-display area NDA. However, at least one dummy sub-pixel that is not directly involved in image display can be arranged in the non-display area NDA. The non-display area NDA can include the first non-display area NDA1, the bending area BA, and the second non-display area NDA2.

The first non-display area NDA1 can be located around the display area DA and can be the region closest to the display area DA among the first non-display area NDA1, the bending area BA, and the second non-display area NDA2.

The second non-display area NDA2 can include the pad areas PA1 and PA2, where various pads are arranged, and can be the region farthest from the display area DA among the first non-display area NDA1, the bending area BA, and the second non-display area NDA2.

The bending area BA is a region where the substrate 111 bends and can be located between the first non-display area NDA1 and the second non-display area NDA2.

The substrate 111 can include the display area DA, where an image is displayed, and the non-display area NDA, which is the peripheral area of the display area DA. A plurality of sub-pixels SP can be arranged in the display area DA. The non-display area NDA can include the GIP (Gate-In-Panel) area, where a GIP-type gate driving circuit is formed, as well as the bending area BA and the second non-display area NDA2, where various lines pass through and the data driving circuit is electrically connected.

For example, the GIP (Gate-In-Panel) area can be located in the left and/or right peripheral regions of the display area DA. The non-display area NDA can be located in the upper or lower peripheral region of the display area DA. The bending area BA can be an outer region beyond the second non-display area NDA2, where a printed circuit board can be electrically connected.

As described above, the substrate 111 can include the bending area BA, which bends and folds. The bending area BA can fold and be positioned on the lower surface or other parts of the unfolded portion. The bending area BA, as a part of the non-display area NDA, can be located between the driving circuit area, where the data driving circuit is electrically connected, and the display area DA.

A plurality of driving voltage lines VDDL for supplying the driving voltage VDD to the sub-pixels SP and at least one reference voltage line VSSL for applying the reference voltage VSS to the common electrode CE of the light-emitting device ED in each sub-pixel SP can be further arranged on the substrate 111.

The reference voltage line VSSL can be arranged in the non-display area NDA to surround the periphery of the display area DA for efficient transmission of the reference voltage VSS. Additionally, the reference voltage line VSSL can pass through the bending area BA and be electrically connected to a data driving circuit in the driving circuit area or a printed circuit board.

The substrate 111 can include a crack prevention pattern PCD. The crack prevention pattern PCD can be formed outside the reference voltage line VSSL in the non-display area NDA, but is not limited thereto.

For example, the crack prevention pattern PCD is a pattern to prevent cracks in the lines passing through the substrate 111 and can be formed in a zigzag pattern, but is not limited thereto.

For example, among the signal lines passing through the bending area BA, some can develop cracks (electrical open state) or become short-circuited with adjacent signal lines when the bending area BA is bent. In such cases, if a signal line develops a crack (open state) or a short circuit, accurate signal transmission can be disrupted, causing issues in display operation and resulting in improper image display. Consequently, image quality can significantly degrade. To prevent this, the crack prevention pattern (PCD) can be included, but is not limited thereto.

As described above, the display panel 110 includes the substrate 111, and by bending the bending area BA, which is the part where the data driving circuit is connected, a portion of the substrate 111 is folded backward. The fold bending area BA becomes a non-visible portion where an image cannot be displayed from the front. Accordingly, by utilizing the bending structure and the line layout as shown in FIG. 3, the bezel size of the display device 100 can be significantly reduced.

The pad areas PA1 and PA2 can include the first pad area PA1 and the second pad area PA2. The pad areas PA1 and PA2 can be located in the second non-display area NDA2. The first pad area PA1 and the second pad area PA2 shown in FIG. 3 can correspond to the first pad area PA1 and the second pad area PA2 shown in FIG. 1. The size and position of the pad areas PA1 and PA2 can vary depending on the design of the display panel 110.

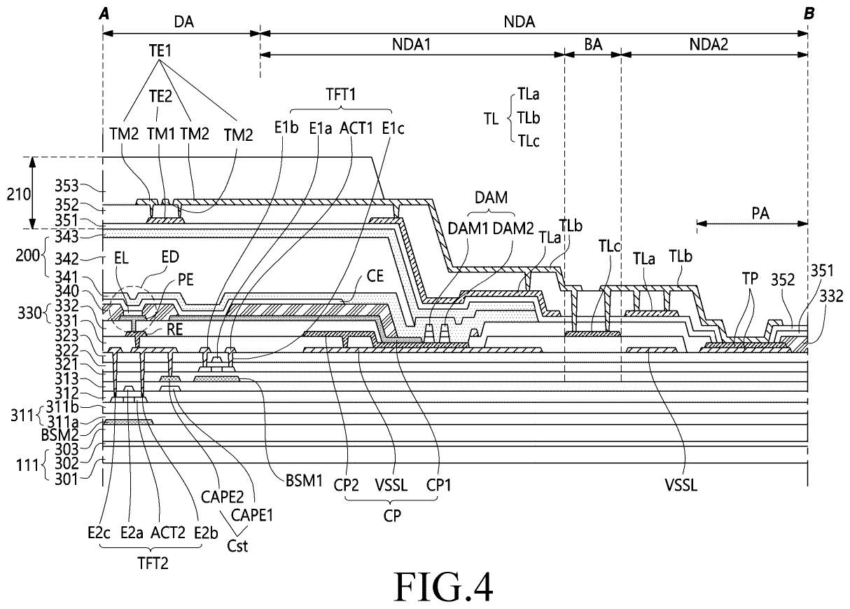

FIG. 4 is a diagram illustrating an example of the cross-sectional structure of the display panel 110 shown in FIG. 3 according to embodiments of the present disclosure.

Referring to FIG. 4, the display panel 110 according to embodiments of the present disclosure can include the substrate 111, the transistor portion, the light-emitting device portion, and the encapsulation portion. However, embodiments of the present disclosure are not limited thereto.

The substrate 111 can be a single-layer or a multi-layer structure. When the substrate 111 is a multi-layer structure, it can include the first substrate 301, the intermediate substrate 302, and the second substrate 303. The intermediate substrate 302 can be located between the first substrate 301 and the second substrate 303. For example, each of the first substrate 301 and the second substrate 303 can be a polyimide (PI) layer, but embodiments of the present disclosure are not limited thereto. The intermediate substrate 302 can be an inorganic insulating layer, but is not limited thereto. The intermediate substrate 302 can prevent electric charge from affecting the transistors arranged on the second substrate 303, which is a polyimide layer, when charge accumulates on the first substrate 301, which is a polyimide layer.

Additionally, the intermediate substrate 302 can block moisture from penetrating upward through the first substrate 301. For example, the intermediate substrate 302 can be formed as a single layer or multiple layers of silicon nitride (SiNx) or silicon oxide (SiOx). It can also be formed as a double layer of silicon dioxide (SiO₂) and silicon nitride (SiNx), but is not limited thereto.

The transistor portion can include the insulating layers 311, 312, 313, 321, 322, and 323 on the substrate 111, the thin-film transistors TFT1 and TFT), the storage capacitor Cst, and various electrodes and signal lines.

The thin-film transistors TFT1 and TFT2 included in the transistor portion can include the first thin-film transistor TFT1 and the second thin-film transistor TFT2.

The first thin-film transistor TFT1 can include the first active layer ACT1, the first electrode E1a, the second electrode E1b, and the third electrode E1c.

The first electrode E1a is a gate electrode, the second electrode E1b can be a source electrode or a drain electrode, and the third electrode E1c can be a drain electrode or a source electrode. Hereinafter, for convenience of explanation, the first electrode E1a is referred to as the first gate electrode E1a, the second electrode E1b as the first source electrode E1b, and the third electrode E1c as the first drain electrode E1c. However, embodiments of the present disclosure are not limited thereto.

The first active layer ACT1 can include the first semiconductor material. For example, the first semiconductor material can include an oxide semiconductor, amorphous silicon, polysilicon, or low-temperature polysilicon (LTPS), but is not limited thereto. The first thin-film transistor TFT1 can be implemented as a p-channel transistor or an n-channel transistor, but embodiments of the present disclosure are not limited thereto.

The second thin-film transistor TFT2 can include the second active layer ACT2, the fourth electrode E2a, the fifth electrode E2b, and the sixth electrode E2c.

The fourth electrode E2a is a gate electrode, the fifth electrode E2b can be a source electrode or a drain electrode, and the sixth electrode E2c can be a drain electrode or a source electrode. Hereinafter, for convenience of explanation, the fourth electrode E2a is referred to as the second gate electrode E2a, the fifth electrode E2b as the second source electrode E2b, and the sixth electrode E2c as the second drain electrode E2c. However, embodiments of the present disclosure are not limited thereto.

The second active layer ACT2 can include the second semiconductor material. For example, the second semiconductor material can include an oxide semiconductor, amorphous silicon, polysilicon, or low-temperature polysilicon (LTPS), but is not limited thereto. The second thin-film transistor TFT2 can be implemented as a p-channel transistor or an n-channel transistor, but embodiments of the present disclosure are not limited thereto.

The types of semiconductor materials for the first active layer ACT1 of the first thin-film transistor TFT1 and the second active layer ACT2 of the second thin-film transistor TFT2 can be as follows.

For example, the first active layer ACT1 of the first thin-film transistor TFT1 and the second active layer ACT2 of the second thin-film transistor TFT2 can include an oxide semiconductor material. In another example, they can include a low-temperature polysilicon (LTPS) semiconductor material. In yet another example, the first active layer ACT1 of the first thin-film transistor TFT1 can include an LTPS semiconductor material, while the second active layer ACT2 of the second thin-film transistor TFT2 can include an oxide semiconductor material. Conversely, the first active layer ACT1 of the first thin-film transistor TFT1 can include an oxide semiconductor material, while the second active layer ACT2 of the second thin-film transistor TFT2 can include an LTPS semiconductor material.

The plurality of transistors can be implemented as follows. In one example, all transistors in each sub-pixel SP can be implemented as the first thin-film transistor TFT1. In another example, all transistors in each sub-pixel SP can be implemented as the second thin-film transistor TFT2. In yet another example, some transistors in each sub-pixel SP can be implemented as the first thin-film transistor TFT1, while the remaining transistors can be implemented as the second thin-film transistor TFT2. For example, each sub-pixel SP can include at least one first thin-film transistor TFT1 and at least one second thin-film transistor TFT2.

If some of the transistors in each sub-pixel SP are implemented as the first thin-film transistor TFT1 and the rest as the second thin-film transistor TFT2, the following examples are possible. For example, in each sub-pixel SP, the driving transistor DT can be implemented as the second thin-film transistor TFT2, while other transistors (e.g., the scan transistor ST or the light-emission control transistor) can be implemented as the first thin-film transistor TFT1. Alternatively, the configuration can be reversed.

In FIG. 4, the second thin-film transistor TFT2, which is connected to the pixel electrode PE of the light-emitting device ED, can be either the driving transistor DT or another transistor depending on the configuration of the sub-pixel circuit SPC. For example, in FIG. 4, the second thin-film transistor TFT2, which is connected between the pixel electrode PE of the light-emitting device ED, can be a light-emission control transistor connected between the driving transistor DT and the light-emitting device ED.

The second active layer ACT2 of the second thin-film transistor TFT2 can be positioned higher than the first active layer ACT1 of the first thin-film transistor TFT1 with respect to the substrate 111.

A first buffer layer 311 can be disposed below the first active layer ACT1 of the first thin-film transistor TFT1, and a second buffer layer 321 can be disposed below the second active layer ACT2 of the second thin-film transistor TFT2. For example, the first active layer ACT1 of the first thin-film transistor TFT1 can be positioned on the first buffer layer 311, and the second active layer ACT2 of the second thin-film transistor TFT2 can be positioned on the second buffer layer 321. The second buffer layer 321 can be positioned higher than the first buffer layer 311.

The storage capacitor Cst can be arranged within various metal layers in the display panel 110. For example, the storage capacitor Cst can include the first capacitor electrode CAPE1 and the second capacitor electrode CAPE2.

The light-emitting device portion can include a plurality of light-emitting devices ED arranged on the planarization layer 330. Each of the plurality of light-emitting devices ED can include a pixel electrode PE, an intermediate layer EL, and a common electrode CE.

The encapsulation portion can include an encapsulation layer 200 on the plurality of light-emitting devices ED. The encapsulation layer 200 can be formed as a single layer or a multilayer structure, but embodiments of the present disclosure are not limited thereto. In addition to the encapsulation layer 200, the encapsulation portion can further include at least one dam (DAM) to prevent the encapsulation material from overflowing. In particular, when the second encapsulation layer 342 included in the encapsulation layer 200 is an organic encapsulation layer made of an organic material, the dam (DAM) can prevent the organic material from overflowing.

Hereinafter, with reference to FIG. 4, the structure or vertical structure of the display panel 110 according to embodiments of the present disclosure will be described in further detail.

Referring to FIG. 4, the first buffer layer 311 can be disposed on the substrate 111. The first buffer layer 311 can be formed as a single layer or a multilayer structure, but embodiments of the present disclosure are not limited thereto. When the first buffer layer 311 is a multilayer structure, it can include a lower buffer layer 311a and an upper buffer layer 311b.

The first active layer ACT1 of the first thin-film transistor TFT1 can be disposed on the first buffer layer 311. The first active layer ACT1 can include a channel region where a channel is formed, a source connection region on one side of the channel region, and a drain connection region on the opposite side of the channel region.

The first gate insulating layer 312 can be disposed on the first active layer ACT1 of the first thin-film transistor TFT1. The first gate electrode E1a of the first thin-film transistor TFT1 can be disposed on the first gate insulating layer 312. The first interlayer insulating layer 313 can be disposed on the first gate electrode E1a of the first thin-film transistor TFT1. Here, the metal layer where the first gate electrode E1a of the first thin-film transistor TFT1 is disposed can be referred to as the first gate metal layer.

The second buffer layer 321 can be disposed on the first interlayer insulating layer 313. The second active layer ACT2 of the second thin-film transistor TFT2 can be disposed on the second buffer layer 321. The second active layer ACT2 can include a channel region where a channel is formed, a source connection region on one side of the channel region, and a drain connection region on the opposite side of the channel region.

The second gate insulating layer 322 can be disposed on the second active layer ACT2 of the second thin-film transistor TFT2. The second gate electrode E2a of the second thin-film transistor TFT2 can be disposed on the second gate insulating layer 322. The second interlayer insulating layer 323 can be disposed on the second gate electrode E2a of the second thin-film transistor TFT2. Here, the second gate electrode E2a of the second thin-film transistor TFT2 can be referred to as the second gate metal layer. An inorganic layer or an organic layer can be disposed on the second interlayer insulating layer 323. Hereinafter, for convenience of explanation, it is assumed that an organic layer is disposed on the second interlayer insulating layer 323.

The first source electrode E1b and the first drain electrode E1c of the first thin-film transistor TFT1, and the second source electrode E2b and the second drain electrode E2c of the second thin-film transistor TFT2 can be disposed on the second interlayer insulating layer 323.

The first source electrode E1b and the first drain electrode E1c of the first thin-film transistor TFT1 can be connected to the source connection region and the drain connection region of the first active layer ACT1 through holes in the second interlayer insulating layer 323, the second gate insulating layer 322, the second buffer layer 321, the first interlayer insulating layer 313, and the first gate insulating layer 312.

The second source electrode E2b and the second drain electrode E2c of the second thin-film transistor TFT2 can be connected to the source connection region and the drain connection region of the second active layer ACT2 through holes in the second interlayer insulating layer 323 and the second gate insulating layer 322, respectively.

The first source electrode E1b and the first drain electrode E1c of the first thin-film transistor TFT1, and the second source electrode E2b and the second drain electrode E2c of the second thin-film transistor TFT2 can include the first source-drain metal and be disposed in the first source-drain metal layer.

For example, the storage capacitor Cst can be formed by the first capacitor electrode CAPE1 and the second capacitor electrode CAPE2. In some cases, the storage capacitor Cst can be formed by three or more capacitor electrodes, or it can have a configuration where two or more capacitors are connected in parallel. Each of the first capacitor electrode CAPE1 and the second capacitor electrode CAPE2 can be disposed in various metal layers within the display panel 110. For example, the first capacitor electrode CAPE1 can include the same first gate metal as the first gate electrode E1a of the first thin-film transistor TFT1, which is disposed on the first gate insulating layer 312, and can be disposed in the first gate metal layer, but embodiments of the present disclosure are not limited thereto. For example, the second capacitor electrode CAPE2 can be disposed on the first interlayer insulating layer 313.

The second source electrode E2b of the second thin-film transistor TFT2 can be electrically connected to the second capacitor electrode CAPE2 through holes in the second interlayer insulating layer 323, the second gate insulating layer 322, and the second buffer layer 321.

For example, when the sub-pixel SP is configured as shown in FIG. 2, the first thin-film transistor TFT1 can correspond to the scan transistor ST in FIG. 2, and the second thin-film transistor TFT2 can correspond to the driving transistor DT in FIG. 2.

The transistor portion can further include a first shield pattern BSM1 disposed on the substrate 111. The first shield pattern BSM1 can overlap the first active layer ACT1 of the first thin-film transistor TFT1. The first shield pattern BSM1 can be disposed below the first active layer ACT1 of the first thin-film transistor TFT1. For example, the first shield pattern BSM1 can be disposed between the substrate 111 and the first buffer layer 311, or it can be disposed between the lower buffer layer 311a and the upper buffer layer 311b.

The transistor portion can further include a second shield pattern BSM2 disposed on the substrate 111. The second shield pattern BSM2 can overlap the second active layer ACT2 of the second thin-film transistor TFT2. The second shield pattern BSM2 can be disposed below the second active layer ACT2 of the second thin-film transistor TFT2. For example, the second shield pattern BSM2 can be disposed in a metal layer between the first interlayer insulating layer 313 and the second buffer layer 321. The second shield pattern BSM2 can be disposed in the same metal layer as the second capacitor electrode CAPE2, but embodiments of the present disclosure are not limited thereto. In another example, the second shield pattern BSM2 can be disposed in the same first gate metal layer as the first gate electrode E1a of the first thin-film transistor TFT1.

The planarization layer 330 can be disposed on the first thin-film transistor TFT1 and the second thin-film transistor TFT2, and can be disposed below the light-emitting device ED. The planarization layer 330 can be an organic insulating layer including an organic insulating material.

In one example, the planarization layer 330 can be formed as a single layer. In another example, the planarization layer 330 can include two layers, such as a first planarization layer 331 and a second planarization layer 332. In yet another example, the planarization layer 330 can include three or more layers. Embodiments of the present disclosure are not limited thereto.

The first planarization layer 331 can be disposed on the first source electrode E1b and the first drain electrode E1c of the first thin-film transistor TFT1, and on the second source electrode E2b and the second drain electrode E2c of the second thin-film transistor TFT2. For example, the first planarization layer 331 can be disposed on the first thin-film transistor TFT1 and the second thin-film transistor TFT2. In another example, the first planarization layer 331 can be disposed while covering both the first thin-film transistor TFT1 and the second thin-film transistor TFT2.

The connection electrode RE can be disposed on the first planarization layer 331. The connection electrode RE can electrically connect the second source electrode E2b of the second thin-film transistor TFT2 to the pixel electrode PE.

The connection electrode RE can be electrically connected to the second source electrode E2b of the second thin-film transistor TFT2 through a hole in the first planarization layer 331. The second source electrode E2b of the second thin-film transistor TFT2 can be electrically connected to the second capacitor electrode CAPE2 of the storage capacitor Cst.

The connection electrode RE can be disposed in the second source-drain metal layer on the first planarization layer 331 and can include the second source-drain metal. The second planarization layer 332 can be disposed on the connection electrode RE.

The light-emitting device portion can be disposed on the second planarization layer 332. The light-emitting device ED can be formed on the second planarization layer 332 and can include a pixel electrode PE, an intermediate layer EL, and a common electrode CE. The light-emitting area of the light-emitting device ED can be formed in a region where the pixel electrode PE, the intermediate layer EL, and the common electrode CE overlap and are in contact.

The pixel electrode PE can be disposed on the second planarization layer 332 and can be electrically connected to the connection electrode RE through a hole in the second planarization layer 332.

The bank 340 can be disposed on the pixel electrode PE. An opening of the bank 340 can expose a portion of the pixel electrode PE to form the light-emitting area. The opening of the bank 340 can overlap a portion of the pixel electrode PE. For example, the bank 340 can be composed of a material containing a black pigment, or an organic material such as benzocyclobutene resin, polyimide resin, acrylic resin, or a photosensitive polymer, but embodiments of the present disclosure are not limited thereto. When the bank 340 is composed of a material containing a black pigment or a black dye, it can be referred to as a black bank. If the bank 340 includes a material containing a black pigment or a black dye, it can block external light or prevent light from being reflected externally, thereby improving the luminance of the display device 100.

The intermediate layer EL of the light-emitting device ED can be disposed on a portion of the pixel electrode PE and the bank 340. The common electrode CE can be disposed on the intermediate layer EL.

The encapsulation portion can be disposed on the light-emitting device portion and can be positioned on the common electrode CE. The encapsulation portion can include an encapsulation layer 200 formed on the common electrode CE. The encapsulation layer 200 can prevent moisture or oxygen from penetrating into the light-emitting device ED. For example, the encapsulation layer 200 can prevent moisture or oxygen from penetrating into the organic material included in the intermediate layer EL of the light-emitting device ED.

The encapsulation layer 200 can be formed as a single layer or a multilayer structure, but embodiments of the present disclosure are not limited thereto. In one example, the encapsulation layer 200 can include a first encapsulation layer 341, a second encapsulation layer 342, and a third encapsulation layer 343, but embodiments of the present disclosure are not limited thereto. For example, the first encapsulation layer 341 and the third encapsulation layer 343 can include an inorganic encapsulation layer, while the second encapsulation layer 342 can include an organic encapsulation layer, but embodiments of the present disclosure are not limited thereto.

The display panel 110 according to embodiments of the present disclosure can further include a touch sensor. In this case, the display panel 110 according to embodiments of the present disclosure can be disposed on the encapsulation layer 200 and can include a touch sensor layer 210 in which the touch sensor is formed.

The touch sensor layer 210 can include a plurality of touch electrodes TE corresponding to the touch sensor and can include at least one touch metal layer for forming the plurality of touch electrodes TE.

For example, in order to form a plurality of touch electrodes TE, the touch sensor layer 210 can include a first touch metal layer in which a plurality of first touch metals TM1 are disposed and a second touch metal layer in which a plurality of second touch metals TM2 are disposed. The first touch metal TM1 and the second touch metal TM2 can refer to structures or materials included in the configuration. In this case, the touch sensor layer 210 can further include a touch interlayer insulating layer 352 disposed between the first touch metal layer and the second touch metal layer. For example, one of the first touch metal layer and the second touch metal layer can be a sensor metal layer, while the other can be a bridge metal layer.

In one example, the first touch metal layer can be the bridge metal layer, while the second touch metal layer can be the sensor metal layer. In this case, a plurality of second touch metals TM2 disposed in the second touch metal layer can be sensor metals forming the touch sensor, while a plurality of first touch metals TM1 disposed in the first touch metal layer can be bridge metals that electrically connect the plurality of second touch metals TM2. For example, two or more second touch metals TM2 and at least one first touch metal TM1 can form a first touch electrode TE1. In this case, two or more second touch metals TE2 can be electrically connected by at least one second touch metal TM2.

The touch sensor layer 210 can further include a touch buffer layer 351 disposed on the encapsulation layer 200. The touch buffer layer 351 can be disposed between the encapsulation layer 200 and the touch metal layer. For example, the first touch metal layer can be disposed on the touch buffer layer 351, and the touch interlayer insulating layer 352 can be disposed on the first touch metal layer.

The touch sensor layer 210 can further include a touch protection layer 353 disposed while covering the touch metal layer. For example, the touch protection layer 353 can be disposed on the second touch metal layer.

For example, the touch buffer layer 351 can be an inorganic layer including an inorganic insulating material or an organic layer including an organic insulating material. Similarly, the touch interlayer insulating layer 352 and the touch protection layer 353 can be an inorganic layer including an inorganic insulating material or an organic layer including an organic insulating material.

For example, at least one of the touch buffer layer 351 and the touch interlayer insulating layer 352 can be extended from the display area DA to the non-display area NDA. The touch protection layer 353 can also be extended from the display area DA to the non-display area NDA.

The touch routing line TL can electrically connect the touch electrode TE to the touch pad TP. The touch routing line TL can be composed of at least one of the first touch metal TM1 and the second touch metal TM2.

For example, the touch routing line TL can be composed of the first touch metal TM1, the second touch metal TM2, or both. When a single touch routing line TL is composed of both the first touch metal TM1 and the second touch metal TM2, these metals can be electrically connected through a hole in the touch interlayer insulating layer 352.

For example, a single touch routing line TL can include multiple line sections, each of which can be either a single line section or a double line section. Here, a single line section refers to a line section with one signal path, while a double line section refers to a line section with two signal paths connected in parallel.

The touch routing line TL can be disposed along a slope of the encapsulation layer 200 and can extend past the dam DAM1 and DAM2 to the touch pad TP.

The touch buffer layer 351 can have an opening that exposes at least a portion of the touch pad TP. The touch routing line TL can be electrically connected to the touch pad TP through the opening in the touch buffer layer 351. The touch interlayer insulating layer 352 can be disposed on the touch routing line TL and can extend to the area where the touch pad TP is disposed. The touch protection layer 353 can be disposed only in the display area DA or can extend to the non-display area NDA and be disposed on an upper portion of the touch routing line TL as well. In some cases, the touch protection layer 353 can further extend to an upper portion of the touch pad TP.

Each of the plurality of touch electrodes TE can be a mesh-type electrode having multiple openings. In this case, each of the plurality of touch electrodes TE can be composed of at least one second touch metal TM2. However, embodiments of the present disclosure are not limited thereto.

The plurality of first touch metals TM1 and the plurality of second touch metals TM2 can be disposed so as not to overlap the light-emitting device ED. The plurality of first touch metals TM1 and the plurality of second touch metals TM2 can overlap the bank 340. Accordingly, the light-emitting efficiency of the light-emitting device ED can be improved.

The touch routing line TL can electrically connect the touch pad TP, which is disposed in the pad area PA of the second non-display area NDA2, and the first touch electrode TE1, which is disposed in the display area DA. To achieve this, the touch routing line TL can be disposed across the second non-display area NDA2, the bending area BA, and the first non-display area NDA1.

The touch routing line TL can include a first line section TLa, a second line section TLb, and a third line section TLc. For example, the touch routing line TL can include the first line section TLa and the second line section TLb, which are disposed in the first non-display area NDA1 and the second non-display area NDA2, and the third line section TLc, which is disposed in the bending area BA. The third line section TLc can electrically connect the first line section TLa and the second line section TLb.

The first line section TLa of the touch routing line TL can be a single line section and can further include a third touch metal layer, in which a third touch metal TM3 is disposed. The first line section TLa of the touch routing line TL can extend along a slope of the encapsulation layer 200 and can be disposed extending over at least one dam DAM1 or DAM2. For example, the first line section TLa of the touch routing line TL can extend to the third line section TLc of the touch routing line TL through at least one of the first touch metal layer and the second touch metal layer.

The second line section TLb of the touch routing line TL can include at least one of the first touch metal layer, in which the first touch metal TM1 is disposed, and the second touch metal layer, in which the second touch metal TM2 is disposed. For example, the second line section TLb of the touch routing line TL can be composed of the second touch metal layer. In another example, the second line section TLb of the touch routing line TL can be formed by electrically connecting the first touch metal layer and the second touch metal layer.

For example, the second line section TLb of the touch routing line TL can be electrically connected to the touch pad TP through a contact hole penetrating the second planarization layer 332, the touch buffer layer 351, and the touch interlayer insulating layer 352. For example, the third line section TLc of the touch routing line TL can extend to the second line section TLb of the touch routing line TL.

The third line section TLc of the touch routing line TL can include a metal layer different from the first to third touch metal layers, in which the first to third touch metals TM1, TM2, and TM3 are disposed. For example, the metal layer included in the third line section TLc of the touch routing line TL can be the same as the metal layer in which an electrode or line for display driving is disposed. For example, the metal layer included in the third line section TLc of the touch routing line TL can include the metal layer in which the pixel electrode PE is disposed, but embodiments of the present disclosure are not limited thereto.

The touch pad TP can be electrically connected to the second line section TLb of the touch routing line TL and can include a metal layer different from the first to third touch metal layers. For example, the metal layer included in the touch pad TP can be the same as the metal layer in which an electrode or line for display driving is disposed. For example, the metal layer included in the touch pad TP can include a metal layer in which the pixel electrode PE is disposed, but embodiments of the present disclosure are not limited thereto.

The display panel 110 of the display device 100 according to embodiments of the present disclosure can further include a common voltage line VSSL, to which a common voltage VSS is applied, and a connection pattern CP, which connects the common electrode CE to the common voltage line VSSL. For example, the connection pattern CP can include the same material as the pixel electrode PE. For example, the connection pattern CP can include a first connection pattern CP1 and a second connection pattern CP2. For example, the first connection pattern CP1 can connect the common electrode CE to the second connection pattern CP2, and the second connection pattern CP2 can connect the first connection pattern CP1 to the common voltage line VSSL, but embodiments of the present disclosure are not limited thereto.

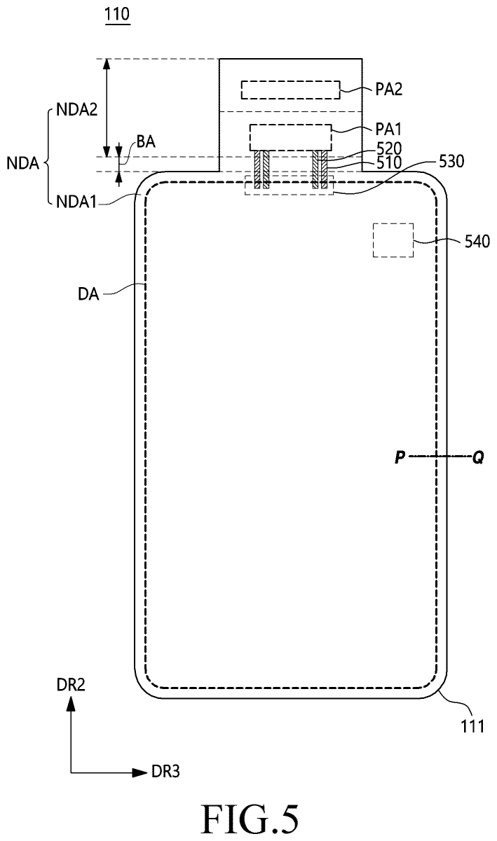

FIG. 5 is a plan view of the display panel 110 including voltage lines 510 and 520 according to embodiments of the present disclosure.

Referring to FIG. 5, the display panel 110 can include a substrate 111, which can include a display area DA and a non-display area NDA. The non-display area NDA can include a first non-display area NDA1, a second non-display area NDA2, and a bending area BA. A first pad area PA1 and a second pad area PA2 can be located in the second non-display area NDA2. The features of the display panel 110 shown in FIG. 5 can be the same as those of the display panel 110 shown in FIG. 3, and redundant descriptions will be omitted.

The voltage lines 510 and 520 can extend from the non-display area NDA to the display area DA and can supply voltage to components disposed in the display area DA.

The voltage lines 510 and 520 can be positioned adjacent to the first pad area PA1 and can extend from the bending area BA to the display area DA. The voltage lines 510 and 520 can have a linear shape.

The voltage lines 510 and 520 can be supplied with a driving voltage, a reference voltage, or an initialization voltage. The voltage lines 510 and 520 can include two or more voltage lines. For example, they can include a line supplying a driving voltage, a line supplying a reference voltage, and a line supplying an initialization voltage. For convenience of explanation, the first voltage line 510 or 520 can be defined as a driving voltage line, which is supplied with a driving voltage, or can be defined as a lower voltage line. The second voltage line 510 or 520 can be defined as a reference voltage line, which is supplied with a reference voltage, or can be defined as an upper voltage line.

Referring to FIG. 3, it can be confirmed that the common voltage line VSSL is disposed in the first non-display area NDA1. The common voltage line VSSL can be arranged in a form that surrounds the first non-display area NDA1. The common voltage line VSSL can be arranged in a ring shape. If the common voltage line VSSL is not arranged in a ring shape but is disposed inside the display area DA, the bezel size can be further reduced.

Accordingly, embodiments of the present disclosure can provide a display device 100 capable of reducing the bezel size by disposing the voltage lines 510 and 520 in the display area DA.

According to embodiments of the present disclosure, a display device 100 can be provided that can reduce the bezel size by disposing the voltage lines 510 and 520 in the display area DA.

According to embodiments of the present disclosure, a display device 100 can be provided that can simplify the circuit arrangement of the non-display area NDA by disposing the voltage lines 510 and 520 in the display area DA.

According to embodiments of the present disclosure, a display device 100 can be provided that can reduce voltage drop by patterning the voltage lines 510 and 520 into a specific shape.

According to embodiments of the present disclosure, a display device 100 can be provided that can reduce the effect of external light on thin-film transistors (TFTs) by patterning the voltage lines 510 and 520 into a specific shape.

According to embodiments of the present disclosure, a display device 100 can be provided that can operate at low power consumption by reducing voltage drop and protecting thin-film transistors (TFTs) from external light.

Referring to FIG. 5, a first region 530 in which the voltage lines 510 and 520 extending from the non-display area NDA to the display area DA are disposed can be identified. Referring to FIG. 5, a second region 540, which is a part of the display area DA, can be identified. Referring to FIG. 5, a P-Q area, which extends from the display area DA to the non-display area NDA, can also be identified. The following describes the cross-sectional views of the first area 530, the second area 540, and the P-Q area in order.

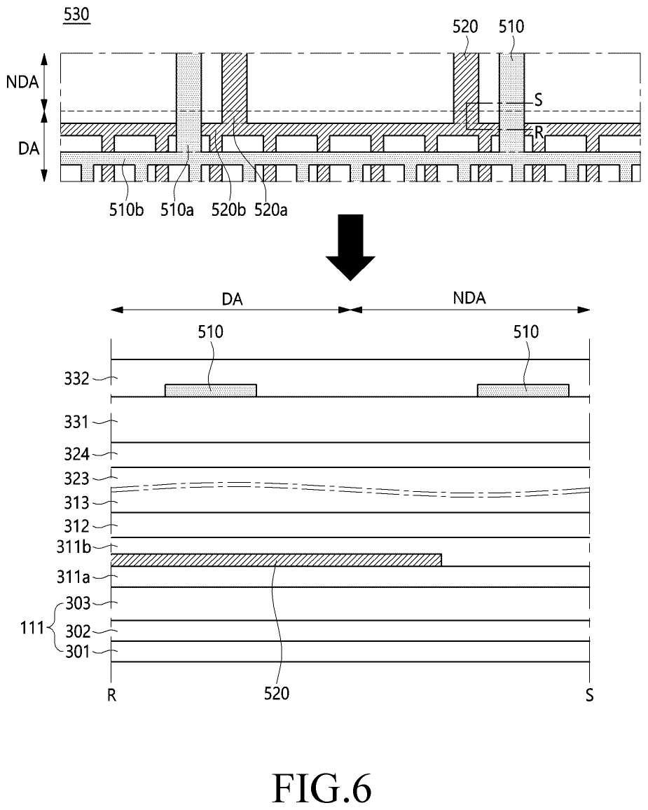

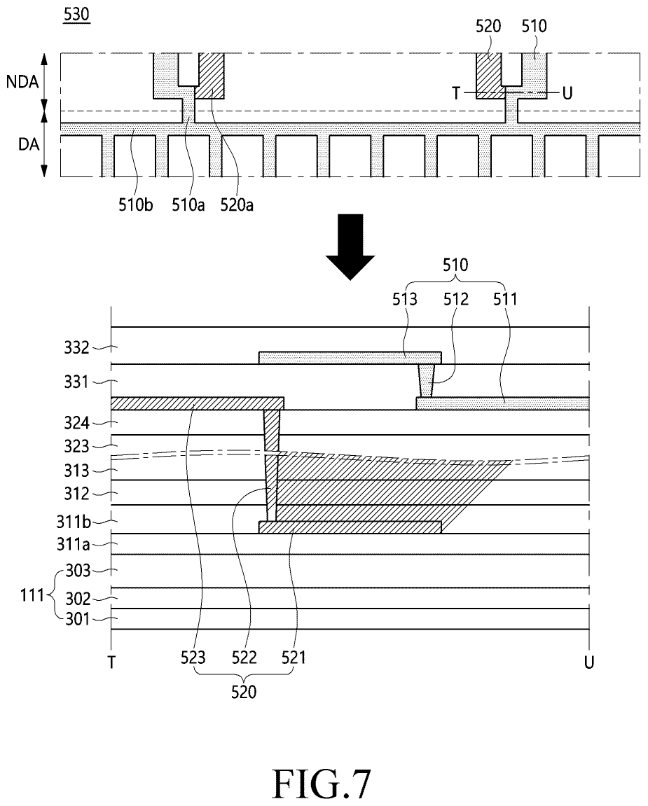

FIG. 6 and FIG. 7 are diagrams related to the voltage lines 510 and 520 disposed in the display area DA and the non-display area NDA shown in FIG. 5.

Referring to FIG. 6 and FIG. 7, the first area 530 is an area where the voltage lines 510 and 520 extending from the non-display area NDA to the display area DA are disposed. The first area 530 includes a reference voltage line 510 and a driving voltage line 520, and their example top views can be identified. After describing the reference voltage line 510 and the driving voltage line 520 shown in FIG. 6, the description will continue with those shown in FIG. 7.

Referring to FIG. 6, the reference voltage line 510 can extend from the non-display area NDA to the display area DA. The reference voltage line 510 can include two line portions, one of which can be positioned relatively on the left side, while the other can be positioned relatively on the right side.

The driving voltage line 520 can extend from the non-display area NDA to the display area DA. The driving voltage line 520 can include two line portions, one of which can be positioned relatively on the left side, while the other can be positioned relatively on the right side. One of the two line portions can be positioned relatively further to the left than the reference voltage line 510, while the other can be positioned relatively further to the right than the reference voltage line 510.

The reference voltage line 510 can extend from the non-display area NDA to the display area DA, and the portion of the reference voltage line 510 located in the display area DA can be in a mesh pattern. The reference voltage line 510 can include a linear portion 510a and a mesh portion 510b. The linear portion 510a can be a straight-line section extending from the non-display area NDA to the display area DA. The mesh portion 510b can be a section arranged in a mesh pattern in the display area DA.

The driving voltage line 520 can extend from the non-display area NDA to the display area DA, and the portion of the driving voltage line 520 located in the display area DA can be in a mesh pattern. Referring to FIG. 6, the driving voltage line 520 can include a linear portion 520a and a mesh portion 520b. The linear portion 520a can be a straight-line section extending from the non-display area NDA to the display area DA. The mesh portion 520b can be a section arranged in a mesh pattern in the display area DA.

The mesh pattern can be a pattern in which lines extend in both the horizontal and vertical directions. The mesh pattern can be a plate pattern that includes multiple hole areas. The reference voltage line 510 and the driving voltage line 520 can be deposited over the entire display area DA and then etched into a mesh pattern.

Referring to the top view shown in FIG. 6, an R-S area marked on the reference voltage line 510 and the driving voltage line 520 can be identified. The following describes a cross-sectional view of the R-S area.

Referring to FIG. 6, the display panel 110 can include a first substrate 301, an intermediate substrate 302, a second substrate 303, a first buffer layer 311a, a second buffer layer 311b, a first gate insulation layer 312, a first interlayer insulation layer 313, a second interlayer insulation layer 323, a first planarization layer 331, and a second planarization layer 332. The aforementioned components shown in FIG. 6 can be the same as the first substrate 301, the intermediate substrate 302, the second substrate 303, the first buffer layer 311a, the second buffer layer 311b, the first gate insulation layer 312, the first interlayer insulation layer 313, the second interlayer insulation layer 323, the first planarization layer 331, and the second planarization layer 332 shown in FIG. 4. Therefore, repetitive descriptions will be omitted.

The reference voltage line 510 can be disposed on the first buffer layer 311a. After being deposited on the first buffer layer 311a, the reference voltage line 510 can be etched into a linear shape in the non-display area NDA and into a mesh shape in the display area DA. A second buffer layer 311b can be disposed on the reference voltage line 510. The reference voltage line 510 can include a material that is included in the second shield pattern BSM2.

Although the reference voltage line 510 is illustrated as being disposed on the first buffer layer 311a, it can also be disposed on the second substrate 303. Even when the reference voltage line 510 is disposed on the second substrate 303, it can still include a material that is included in the second shield pattern BSM2.

The driving voltage line 520 can be disposed on the first planarization layer 331. An intermediate insulation layer 324 can be disposed between the first planarization layer 331 and the second interlayer insulation layer 323. The intermediate insulation layer 324 can include an inorganic material.

Referring to the top view of FIG. 6, the R-S area extends through the driving voltage line 520 in the non-display area NDA and also extends through the driving voltage line 520 in the display area DA. Accordingly, referring to the cross-sectional view shown in FIG. 6, it can be seen that the driving voltage line 520 is disposed in both the display area DA and the non-display area NDA.

After being deposited on the first planarization layer 331, the driving voltage line 520 can be etched into a linear shape in the non-display area NDA and into a mesh shape in the display area DA. A second planarization layer 332 can be disposed on the driving voltage line 520. The driving voltage line 520 can include a material that is included in the second source-drain metal layer.

Subsequently the reference voltage line 510 and the driving voltage line 520 shown in FIG. 7 will be described.

Referring to FIG. 7, the reference voltage line 510 can extend from the non-display area NDA to the display area DA. The reference voltage line 510 can include two line portions, one of which can be positioned relatively on the left side, while the other can be positioned relatively on the right side.

The driving voltage line 520 can extend from the non-display area NDA to the display area DA. The driving voltage line 520 can include two line portions, one of which can be positioned relatively on the left side, while the other can be positioned relatively on the right side. One of the two line portions can be positioned relatively further to the left than the reference voltage line 510, while the other can be positioned relatively further to the right than the reference voltage line 510.

A portion of the reference voltage line 510 can overlap with a portion of the driving voltage line 520 in the non-display area NDA. Based on the top view of FIG. 7, the reference voltage line 510 and the driving voltage line 520 can extend from the non-display area NDA to the display area DA while being spaced apart from each other. However, the reference voltage line 510 and the driving voltage line 520 can overlap in an area adjacent to the display area DA.

The reference voltage line 510 and the driving voltage line 520 can overlap in the display area DA. The reference voltage line 510 and the driving voltage line 520 can have a mesh pattern. These voltage lines can be formed using the same mask, which reduces the number of masks required. Accordingly, process optimization can be achieved.

The reference voltage line 510 can include a linear portion 510a and a mesh portion 510b. The linear portion 510a can be a straight-line section extending from the non-display area NDA to the display area DA. The mesh portion 510b can be a section arranged in a mesh pattern in the display area DA. Similarly, the driving voltage line 520 can include a linear portion 520a and a mesh portion, with its mesh portion being located below the reference voltage line 510.

Referring to the top view of FIG. 7, a T-U area, which extends across the reference voltage line 510 and the driving voltage line 520 in the non-display area NDA, can be identified. The following describes the T-U area.

Referring to the cross-sectional view of FIG. 7, the display panel 110 can include a first substrate 301, an intermediate substrate 302, a second substrate 303, a first buffer layer 311a, a second buffer layer 311b, a first gate insulation layer 312, a first interlayer insulation layer 313, a second interlayer insulation layer 323, a first planarization layer 331, and a second planarization layer 332. The aforementioned components shown in FIG. 7 can be the same as those shown in FIG. 4, and therefore, repetitive descriptions will be omitted.

Referring to FIG. 7, the reference voltage line 510 can include a first reference voltage line portion 511, a second reference voltage line portion 512, and a third reference voltage line portion 513. Similarly, the driving voltage line 520 can include a first driving voltage line portion 521, a second driving voltage line portion 522, and a third driving voltage line portion 523.

The first driving voltage line portion 521 can be disposed on the first buffer layer 311a. The first driving voltage line portion 521 can be electrically connected to the second driving voltage line portion 522 and can overlap the third reference voltage line portion 513. The first driving voltage line portion 521 can be part of the driving voltage line 520 that overlaps the reference voltage line 510. Additionally, the first driving voltage line portion 521 can include a material that is included in the second shield pattern BSM2.

The second driving voltage line portion 522 can be positioned in a contact hole formed in multiple insulation layers 311b, 312, 313, . . . , 323, 324. The second driving voltage line portion 522 can be electrically connected to the third driving voltage line portion 523 and can include a material that is contained in the first source-drain metal layer.

The third driving voltage line portion 523 can be disposed on the intermediate insulation layer 324. The intermediate insulation layer 324 can be located between the first planarization layer 331 and the second interlayer insulation layer 323 and can include an inorganic material. A portion of the third driving voltage line portion 523 can overlap the third reference voltage line portion 513, while another portion may not overlap the reference voltage line 510. Additionally, the third driving voltage line portion 523 can include a material that is contained in the first source-drain metal layer.

The first reference voltage line portion 511 can be disposed on the intermediate insulation layer 324. The first reference voltage line portion 511 can be electrically connected to the second reference voltage line portion 512. A portion of the first reference voltage line portion 511 can overlap the first driving voltage line portion 521, while the remaining portion may not overlap the driving voltage line 520. Additionally, the first reference voltage line portion 511 can include a material that is contained in the first source-drain metal layer.

The second reference voltage line portion 512 can be positioned in a contact hole formed in the first planarization layer 331. The second reference voltage line portion 512 can overlap the driving voltage line 520 and can include a material that is contained in the second source-drain metal layer.

The third reference voltage line portion 513 can be disposed on the first planarization layer 331. The third reference voltage line portion 513 can be electrically connected to the second reference voltage line portion 512 and can overlap the first driving voltage line portion 521. Additionally, the third reference voltage line portion 513 can include a material contained in the second source-drain metal layer.

Referring to the top and cross-sectional views in FIG. 7, the first driving voltage line portion 521 and the third reference voltage line portion 513 can overlap each other and extend from the non-display area NDA to the display area DA while remaining in an overlapping state.

Even in the display area DA, the first driving voltage line portion 521 and the third reference voltage line portion 513 can overlap and can have a mesh pattern.

Referring to FIG. 6 and FIG. 7, the descriptions above cover the reference voltage line 510 and the driving voltage line 520 extending from the non-display area NDA to the display area DA. The following describes the reference voltage line 510 and the driving voltage line 520 disposed in the display area DA.

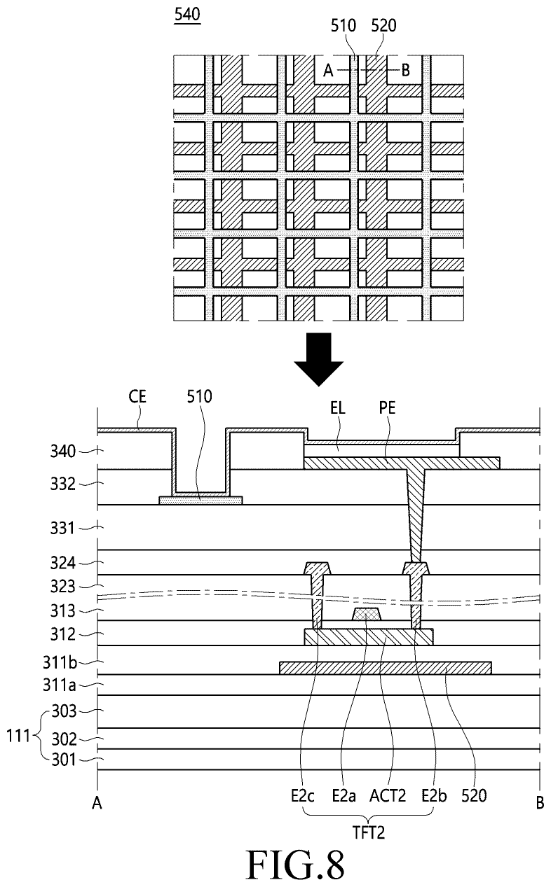

FIG. 8 to FIG. 13 are top and cross-sectional views illustrating the voltage lines 510 and 520 disposed in the display area DA according to embodiments of the present disclosure.

Referring to FIG. 8 to FIG. 13, the reference voltage line 510 and the driving voltage line 520 can be disposed in the display area DA.

Referring to the top views in FIG. 8 to FIG. 13, the driving voltage line 520 can have a mesh pattern.

The reference voltage line 510 can have a metal plate pattern including multiple hole areas HA or can have a mesh pattern.

Referring to FIG. 8 to FIG. 13, the cross-sectional structure of the display panel 110 can be identified. The cross-sectional views shown in FIG. 8 to FIG. 13 indicate that the display panel 110 can include a first substrate 301, an intermediate substrate 302, a second substrate 303, a first buffer layer 311a, a second buffer layer 311b, a first gate insulation layer 312, a first interlayer insulation layer 313, a second interlayer insulation layer 323, a first planarization layer 331, a second planarization layer 332, and a bank 340. These components are the same as those shown in FIG. 4; therefore, repetitive descriptions will be omitted.

The second thin-film transistor (TFT2) can include a second gate electrode E2a, a second source electrode E2b, a second drain electrode E2c, and a second active layer ACT2. The characteristics of the second thin-film transistor (TFT2) are the same as those shown in FIG. 4; therefore, repetitive descriptions will be omitted. The second active layer ACT2 can be disposed on the second buffer layer 311b. The second gate electrode E2a can be disposed on the first gate insulation layer 312 and can include a material contained in the first gate metal layer. The second source electrode E2b and the second drain electrode E2c can be disposed on the second interlayer insulation layer 323 and can be electrically connected to the second active layer ACT2 through a contact hole. Additionally, the second source electrode E2b and the second drain electrode E2c can include a material contained in the first source-drain metal layer. An intermediate insulation layer 324 can be disposed on the second source electrode E2b and the second drain electrode E2c, and the first planarization layer 331 can be disposed on the intermediate insulation layer 324.

The reference voltage line 510 can be disposed on the first planarization layer 331. The common electrode CE can be disposed on the bank 340 and can be electrically connected to the reference voltage line 510 through a contact hole formed in the bank 340 and the second planarization layer 332. The reference voltage supplied through the reference voltage line 510 can be provided to the common electrode CE. The common electrode CE can overlap the intermediate layer EL, which is the light-emitting layer, and is the same as the intermediate layer EL shown in FIG. 4.

The pixel electrode PE can be disposed below the intermediate layer EL and can overlap the intermediate layer EL. The pixel electrode PE can be electrically connected to the second source electrode E2b through contact holes formed in the second planarization layer 332, the first planarization layer 331, and the intermediate insulation layer 324. The pixel electrode PE can be in direct contact with the second source electrode E2b. However, in some cases, the pixel electrode PE can be electrically connected to the second source electrode E2b via an additional electrode disposed between the pixel electrode PE and the second source electrode E2b.

The following describes the reference voltage line 510 and the driving voltage line 520 shown in FIG. 8 to FIG. 13.

Referring to FIG. 8, the second area 540 can be a part of the display area DA. The reference voltage line 510 and the driving voltage line 520 can be disposed in the second area 540 and can have a mesh pattern. Some portions of the reference voltage line 510 can overlap the driving voltage line 520. However, depending on the design, the entire reference voltage line 510 can overlap the driving voltage line 520.

The A-B area, which crosses the reference voltage line 510 and the driving voltage line 520 in the display area DA, can be identified.

Referring to the cross-sectional view of the A-B area in FIG. 8, the driving voltage line 520 can be disposed on the first buffer layer 311a and can be located below the second thin-film transistor TFT2. The driving voltage line 520 can overlap the second active layer ACT2 of the second thin-film transistor TFT2 and protect the second active layer ACT2 from external light.

The reference voltage line 510 can be disposed on the first planarization layer 331 and may not overlap the second thin-film transistor TFT2.

Referring to FIG. 8, the second thin-film transistor TFT2 can be protected from external light by the driving voltage line 520.

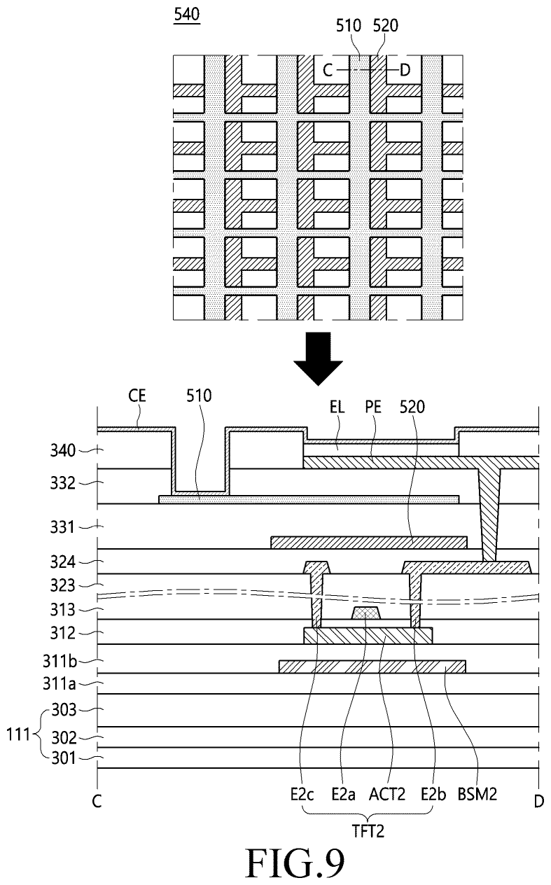

Referring to FIG. 9, the second area 540 can include the reference voltage line 510 and the driving voltage line 520, both of which can have a mesh pattern. Some portions of the reference voltage line 510 can overlap the driving voltage line 520. However, depending on the design, the entire reference voltage line 510 can overlap the driving voltage line 520.

The C-D area, which crosses the reference voltage line 510 and the driving voltage line 520 in the display area DA, can be identified.

Referring to the cross-sectional view of the C-D area in FIG. 9, the driving voltage line 520 can be disposed on the intermediate insulation layer 324 and can overlap the second thin-film transistor TFT2. The driving voltage line 520 can protect the upper portion of the second thin-film transistor TFT2 from external light.

The second shield pattern BSM2 can be disposed on the first buffer layer 311a and can be located below the second thin-film transistor TFT2. The second shield pattern BSM2 can overlap the second active layer ACT2 of the second thin-film transistor TFT2 and protect the second active layer ACT2 from external light.

The reference voltage line 510 can be disposed on the first planarization layer 331 and can overlap the second thin-film transistor TFT2. The reference voltage line 510 can protect the upper portion of the second thin-film transistor TFT2 from external light. Referring to FIG. 8 and FIG. 9, the width of the reference voltage line 510 in the vertical direction can be designed to be relatively wider, allowing the reference voltage line 510 to overlap the second thin-film transistor TFT2.

Referring to FIG. 9, the upper portion of the second thin-film transistor TFT2 can be protected from external light by the reference voltage line 510 and the driving voltage line 520.

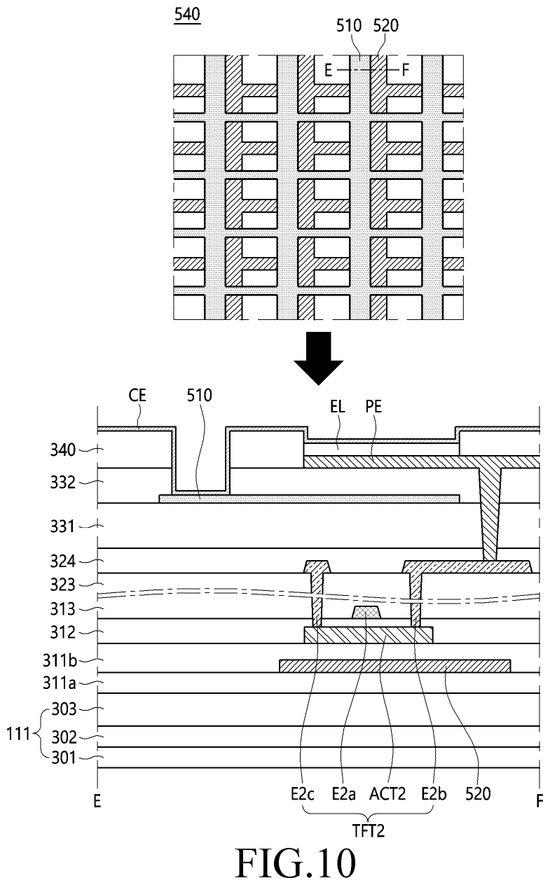

Referring to FIG. 10, the second area 540 can include the reference voltage line 510 and the driving voltage line 520, both of which can have a mesh pattern. Some portions of the reference voltage line 510 can overlap the driving voltage line 520. However, depending on the design, the entire reference voltage line 510 can overlap the driving voltage line 520.

Referring to FIG. 10, the E-F area, which crosses the reference voltage line 510 and the driving voltage line 520 in the display area DA, can be identified.

Referring to the cross-sectional view of the E-F area in FIG. 10, the driving voltage line 520 can be disposed on the first buffer layer 311a and can be located below the second thin-film transistor TFT2. The driving voltage line 520 can overlap the second active layer ACT2 of the second thin-film transistor TFT2 and protect the second active layer ACT2 from external light.

The reference voltage line 510 can be disposed on the first planarization layer 331 and can overlap the second thin-film transistor TFT2. The reference voltage line 510 can protect the upper portion of the second thin-film transistor TFT2 from external light.

Referring to FIG. 10, the second thin-film transistor TFT2 can be protected from external light by the reference voltage line 510 and the driving voltage line 520.

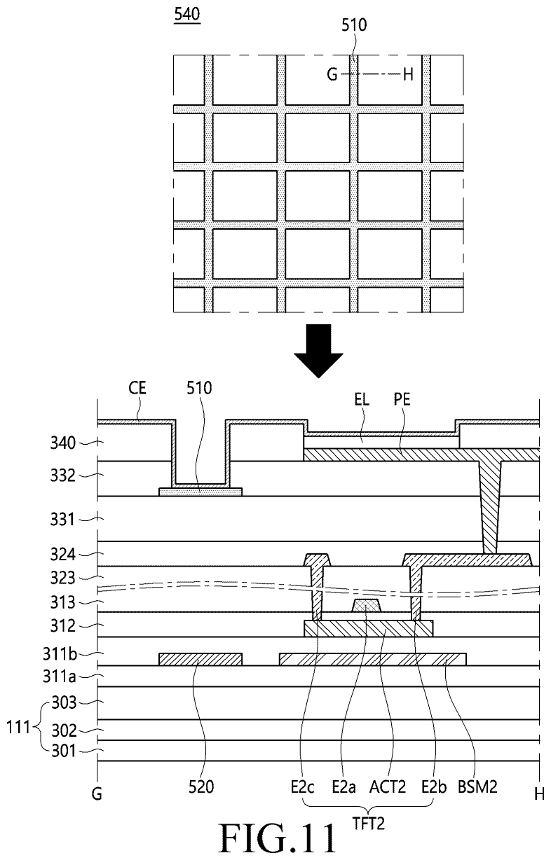

Referring to FIG. 11, the second area 540 can include the reference voltage line 510 and the driving voltage line 520, both of which can have a mesh pattern. The entire reference voltage line 510 can overlap the driving voltage line 520. Since the reference voltage line 510 and the driving voltage line 520 can be formed using the same mask, the process can be optimized, improving process efficiency.

A G-H area crossing the reference voltage line 510 and the driving voltage line 520 in the display area DA can be identified.

Referring to the cross-sectional view of the G-H area in FIG. 11, the reference voltage line 510 can be disposed on the first planarization layer 331. The reference voltage line 510 may not overlap the second thin-film transistor TFT2.

The driving voltage line 520 can be disposed on the first planarization layer 331. The driving voltage line 520 may not overlap the second thin-film transistor TFT2. The driving voltage line 520 can overlap the reference voltage line 510.

The second shield pattern BSM2 can be disposed on the first buffer layer 311a. The second shield pattern BSM2 can be positioned below the second thin-film transistor TFT2. The second shield pattern BSM2 can overlap the second active layer ACT2 of the second thin-film transistor TFT2. The second shield pattern BSM2 can protect the second active layer ACT2 from external light.

Referring to FIG. 11, since the driving voltage line 520 and the reference voltage line 510 can be formed using the same mask, the process can be optimized, improving efficiency.

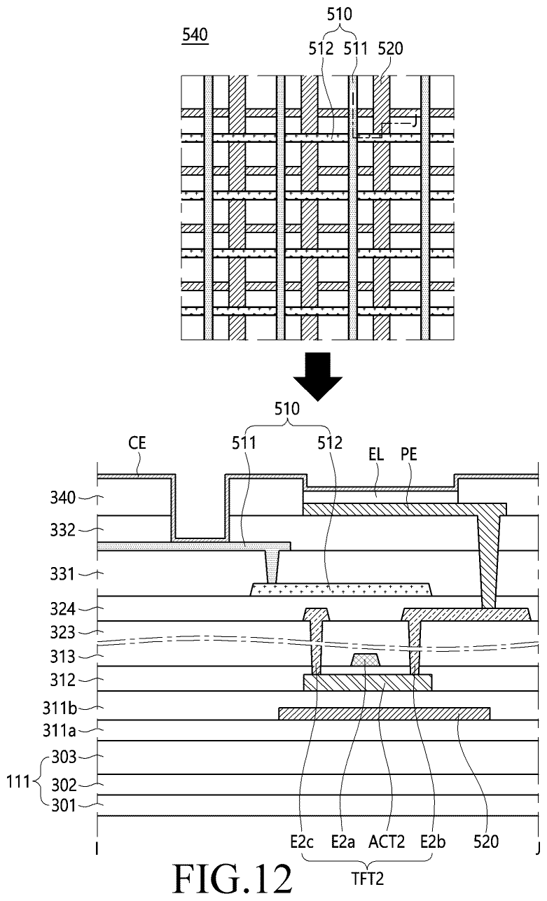

Referring to FIG. 12, the reference voltage line 510 and the driving voltage line 520 can be disposed in the second area 540. The reference voltage line 510 and the driving voltage line 520 can be arranged in a mesh pattern. A portion of the reference voltage line 510 can overlap the driving voltage line 520. However, depending on the design, all portions of the reference voltage line 510 can overlap the driving voltage line 520.

An I-J area crossing the reference voltage line 510 and the driving voltage line 520 in the display area DA can be identified.

Referring to the cross-sectional view of the I-J area in FIG. 12, the driving voltage line 520 can be disposed on the first buffer layer 311a. The driving voltage line 520 can be positioned below the second thin-film transistor TFT2. The driving voltage line 520 can overlap the second active layer ACT2 of the second thin-film transistor TFT2. The driving voltage line 520 can protect the second active layer ACT2 from external light.

The reference voltage line 510 can include a first reference voltage line portion 511 and a second reference voltage line portion 512. Referring to the plan view of FIG. 12, the first reference voltage line portion 511 can extend horizontally, while the second reference voltage line portion 512 can extend vertically.

The first reference voltage line portion 511 can be disposed on the intermediate insulating layer 324 and can overlap the second thin-film transistor TFT2. Since the first reference voltage line portion 511 overlaps the second thin-film transistor TFT2, it can protect the upper portion of the second thin-film transistor TFT2 from external light.

The second reference voltage line portion 512 can be disposed on the first planarization layer 331. The second reference voltage line portion 512 can be electrically connected to the first reference voltage line portion 511 through a contact hole formed in the first planarization layer 331.

Referring to FIG. 12, by designing the reference voltage line 510 across two layers, the metal layer portion disposed on the first planarization layer 331 can be reduced. Since this allows additional metal to be placed in the reduced portion, design flexibility can be improved. Additionally, the driving voltage line 520 can protect the second thin-film transistor TFT2 from external light.

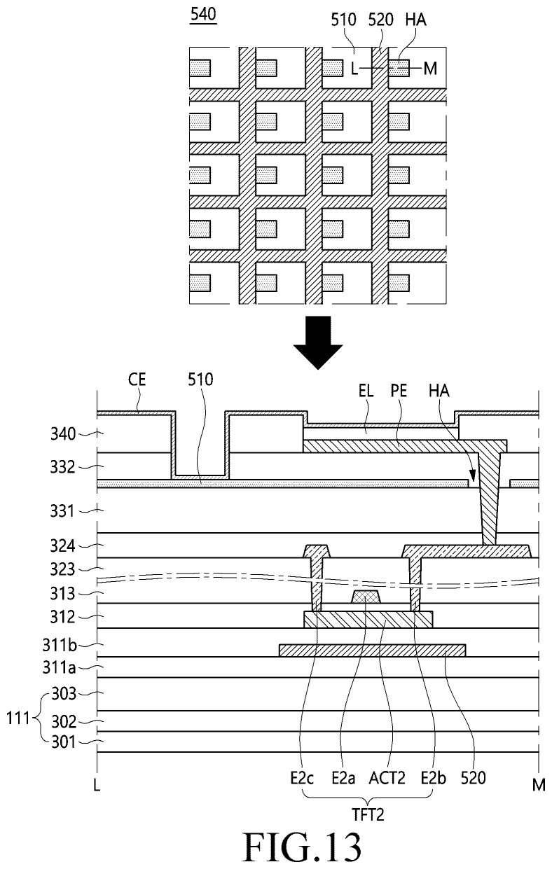

Referring to FIG. 13, the reference voltage line 510 and the driving voltage line 520 can be disposed on the second area 540. The driving voltage line 520 can be arranged in a mesh pattern. The reference voltage line 510 can be entirely deposited over the display area DA and can include multiple hole areas HA. For example, the reference voltage line 510 can be in the form of a metal plate while including multiple hole areas HA.

An L-M area crossing the reference voltage line 510 and the driving voltage line 520 in the display area DA can be identified.

Referring to the cross-sectional view of the L-M area in FIG. 13, the driving voltage line 520 can be disposed on the first buffer layer 311a. The driving voltage line 520 can be positioned below the second thin-film transistor TFT2. The driving voltage line 520 can overlap the second active layer ACT2 of the second thin-film transistor TFT2. The driving voltage line 520 can protect the second active layer ACT2 from external light.

The reference voltage line 510 can be disposed on the first planarization layer 331. The reference voltage line 510 can include hole areas HA. The pixel electrode PE can pass through the hole areas HA and be electrically connected to the second source electrode E2b. When the reference voltage line 510 is formed as a metal plate, the components placed on the metal plate can be arranged flatly. Since the components on the metal plate are arranged evenly, the viewing angle can be improved.

Referring to FIG. 8 to FIG. 13, the characteristics of the reference voltage line 510 and the driving voltage line 520 have been described. However, this is for explanatory purposes, and in addition to the reference voltage line 510 and the driving voltage line 520, initialization voltage lines 510 and 520 can also be included. For example, voltage lines supplying voltages other than the reference voltage and the driving voltage can also be arranged in a mesh pattern within the display area DA. In this case, the voltage line layers patterned in a mesh shape can be arranged on different layers. Additionally, compared to the reference voltage line 510 arranged in a ring shape as shown in FIG. 3, the reference voltage line 510 arranged in a mesh pattern can exhibit a relatively reduced voltage drop phenomenon. Consequently, the display device 100 can be driven with lower power consumption.

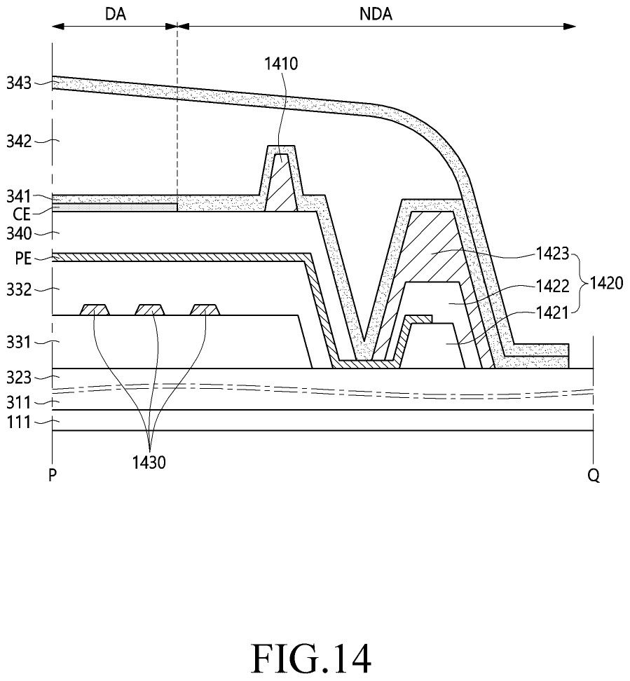

FIG. 14 is a cross-sectional view of the display panel 110, illustrating the display area DA and the non-display area NDA according to embodiments of the present disclosure.

Referring to FIG. 14, the cross-sectional view of the P-Q area shown in FIG. 5 can be identified.

The display panel 110 can include a substrate 111, a first buffer layer 311a, and a second interlayer insulating layer 323, which are the same as the substrate 111, the first buffer layer 311a, and the second interlayer insulating layer 323 shown in FIG. 4. Accordingly, repetitive descriptions are omitted.

The first planarization layer 331 can be disposed on the second interlayer insulating layer 323. The first planarization layer 331 can include an organic material and can be located in the display area DA and the non-display area NDA.

Referring to FIG. 14, signal lines 1430 can be disposed on the first planarization layer 331. The signal lines 1430 can transmit a gate signal, a crack detection signal, or a touch signal. The signal lines 1430 can include a material contained in the second source-drain metal layer.

The second planarization layer 332 can be disposed on the first planarization layer 331. The second planarization layer 332 can include an organic material and can be located in the display area DA and the non-display area NDA. After deposition, a portion of the second planarization layer 332 can be etched and removed. A portion of the second planarization layer 332 can form the first dam portion 1421, which is part of the dam 1420.

The pixel electrode PE can be disposed on the second planarization layer 332. The pixel electrode PE can extend from the display area DA to the non-display area NDA. The pixel electrode PE can extend along the outer side of the second planarization layer 332 and can extend to an upper portion of a part of the first dam portion 1421.

The bank 340 can be disposed on the pixel electrode PE. The bank 340 can include an organic material and can be located in the display area DA and the non-display area NDA. After deposition, a portion of the bank 340 can be etched and removed. A portion of the bank 340 can form the second dam portion 1422, which is part of the dam 1420.

The common electrode CE can be disposed on the bank 340. The common electrode CE can be disposed in the display area DA. The characteristics of the common electrode CE and the pixel electrode PE can be the same as those of the common electrode CE and the pixel electrode PE shown in FIG. 4.

A stopper 1410 can be disposed on the bank 340. The stopper 1410 can be disposed in the non-display area NDA. The stopper 1410 can control the flow of the second encapsulation layer 342. For example, the second encapsulation layer 342 can include an organic material and can flow to the outermost portion of the non-display area NDA. In this case, the stopper 1410 can allow the second encapsulation layer 342 to remain at a specific position. The stopper 1410 can include an organic material. Referring to FIG. 14, a portion of the material included in the stopper 1410 can form the third dam portion 1423, which is part of the dam 1420.

The dam 1420 can be disposed in the non-display area NDA. The dam 1420 can include the first dam portion 1421, the second dam portion 1422, and the third dam portion 1423. The dam 1420 can control the flow of the second encapsulation layer 342.

After the stopper 1410 and the dam 1420 are formed, the first encapsulation layer 341, the second encapsulation layer 342, and the third encapsulation layer 343 can be sequentially formed. The characteristics of the first encapsulation layer 341, the second encapsulation layer 342, and the third encapsulation layer 343 can be the same as those of the first encapsulation layer 341, the second encapsulation layer 342, and the third encapsulation layer 343 shown in FIG. 4.

Referring to FIG. 3, the reference voltage line 510 can be disposed in a ring shape in the non-display area NDA. On the other hand, referring to FIG. 5 to FIG. 13, the reference voltage line 510 is disposed only between the bending area BA and the display area DA in the non-display area NDA, and the other portions of the reference voltage line 510 are disposed in the display area DA. Accordingly, the width of the non-display area NDA can be reduced. Referring to FIG. 14, it can be seen that the reference voltage line 510 is not disposed in the cross-section of the P-Q region.

The display device according to the embodiments of this disclosure can be described as follows.

The embodiments of this disclosure can include voltage lines disposed in a mesh pattern in the display area. The reference voltage line can be located in the display area instead of being arranged in a ring shape in the non-display area. Accordingly, the bezel size can be reduced.

Depending on the placement position, the voltage lines can protect the active layer of the transistor from external light.

Since the voltage lines are arranged in a mesh pattern, voltage drop can occur relatively less.

The embodiments of this disclosure can provide a display device comprising a substrate that comprises a display area and a non-display area outside the display area, a lower voltage line disposed on the substrate to supply a first voltage, a first insulating layer disposed on the lower voltage line, an upper voltage line disposed on the first insulating layer to supply a second voltage different from the first voltage, a second insulating layer disposed on the upper voltage line, a pixel electrode disposed on the second insulating layer, a light-emitting layer disposed on the pixel electrode, and a common electrode disposed on the light-emitting layer. The lower voltage line can be located in the display area and arranged in a first mesh pattern, and the upper voltage line can be electrically connected to the common electrode through a contact hole in the second insulating layer. The upper voltage line can be located in the display area and arranged in a second mesh pattern or a plate patter.

The lower voltage line can include a first linear portion extending from the non-display area to the display area and a first mesh pattern portion located in the display area. The upper voltage line can include a second linear portion extending from the non-display area to the display area and a second mesh pattern portion located in a mesh pattern in the display area.

The display device can further include multiple insulating layers disposed between the upper voltage line and the lower voltage line, and the upper voltage line can be spaced apart from the lower voltage line.

The display device can further include a thin-film transistor (TFT) disposed on the first insulating layer and electrically connected to the pixel electrode, a shield pattern disposed below the thin-film transistor and including a first metal, and a connection electrode disposed between the thin-film transistor and the pixel electrode, electrically connecting the thin-film transistor and the pixel electrode and including a second metal. The upper voltage line can include the second metal, and the lower voltage line can include the first metal.

The first linear portion and the second linear portion can extend from the non-display area to the display area without overlapping each other, and the first linear portion and the second linear portion can overlap in an area adjacent to the display area.

The display device can further include a thin-film transistor disposed on the first insulating layer, including a drain electrode and a source electrode, and electrically connected to the pixel electrode, a shield pattern disposed below the thin-film transistor and including a first metal, a connection electrode disposed between the thin-film transistor and the pixel electrode, electrically connected to the thin-film transistor and the pixel electrode and including a second metal. The first linear portion can include a first section that does not overlap with the second linear portion and contains the metal included in the drain and source electrodes, and a second section that overlaps with the second linear portion and includes the first metal. The second linear portion can include a third section that does not overlap with the first linear portion and contains the metal included in the drain and source electrodes, and a fourth section that overlaps with the first linear portion and includes the second metal.

The display device can further include a thin-film transistor disposed on the first insulating layer, including an active layer and electrically connected to the pixel electrode, wherein the lower voltage line can be disposed below and overlap with the active layer.

The thin-film transistor can be disposed in contact with the pixel electrode or electrically connected via the connection electrode, and the upper voltage line can include the material contained in the connection electrode.

The upper voltage line can be disposed above and overlap with the active layer.

The display device can further include a third insulating layer disposed on the substrate and a thin-film transistor disposed on the third insulating layer and including an active layer, wherein the lower voltage line can be disposed above and overlap with the active layer.

The upper voltage line can be disposed above and overlap with the active layer, and a portion of the upper voltage line can overlap with the lower voltage line.

The display device can further include a shield pattern disposed between the third insulating layer and the active layer and overlapping with the active layer.

The vertically extending portions of the first mesh pattern can overlap with the vertically extending portions of the second mesh pattern, and the horizontally extending portions of the first mesh pattern can overlap with the horizontally extending portions of the second mesh pattern.

The display device can further include a third insulating layer disposed on the substrate, a thin-film transistor disposed on the third insulating layer and including an active layer, and a shield pattern disposed between the third insulating layer and the active layer and overlapping with the active layer. The lower voltage line can include the material contained in the shield pattern.

The display device can further include a thin-film transistor disposed on the first insulating layer and including an active layer. The upper voltage line can include a first upper voltage line portion disposed on the thin-film transistor and overlapping with the active layer and a second upper voltage line portion disposed on the first upper voltage line portion and electrically connected to the first upper voltage line portion.

The first upper voltage line portion can extend in a first direction, and the second upper voltage line portion can extend in a second direction intersecting the first direction.

The lower voltage line can be disposed below and overlap with the active layer.

The display device can include a thin-film transistor disposed on the first insulating layer and including an active layer. The voltage line can be located in the display area and arranged in a plate pattern, which includes multiple hole areas. The pixel electrode can be electrically connected to the thin-film transistor through one of the multiple hole areas.

The lower voltage line can be disposed below and overlap with the active layer.

The non-display area can include a first non-display area adjacent to a first side of the display area, a second non-display area adjacent to a second side of the display area, a third non-display area adjacent to a third side of the display area, and a fourth non-display area adjacent to a fourth side of the display area. The upper voltage line can be disposed in the first non-display area but may not be disposed in the second, third, and fourth non-display areas.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention.

What is claimed is:

1. A display device comprising:
a substrate including a display area and a non-display area outside the display area;
a lower voltage line disposed on the substrate to supply a first voltage;
a first insulating layer disposed on the lower voltage line;
an upper voltage line disposed on the first insulating layer to supply a second voltage different from the first voltage;
a second insulating layer disposed on the upper voltage line;
a pixel electrode disposed on the second insulating layer;
a light-emitting layer disposed on the pixel electrode; and
a common electrode disposed on the light-emitting layer,
wherein the lower voltage line comprises a first mesh portion arranged in a first mesh pattern in the display area,,
wherein the upper voltage line is electrically connected to the common electrode through a contact hole of the second insulating layer, and
wherein the upper voltage line comprises a second mesh portion arranged in a second mesh pattern in the display area or a portion arranged in a plate pattern in the display area.

2. The display device of claim 1, wherein the lower voltage line includes a first linear portion extending from the non-display area to the display area and the first mesh portion, and
wherein the upper voltage line includes a second linear portion extending from the non-display area to the display area and the second mesh portion positioned.

3. The display device of claim 2, further comprising a plurality of insulating layers disposed between the upper voltage line and the lower voltage line,
wherein the upper voltage line is spaced apart from the lower voltage line.

4. The display device of claim 3, further comprising:
a thin-film transistor disposed on the first insulating layer and electrically connected to the pixel electrode;
a shield pattern disposed below the thin-film transistor and including a first metal; and
a connection electrode disposed between the thin-film transistor and the pixel electrode, electrically connected to the thin-film transistor and the pixel electrode, and including a second metal,
wherein the upper voltage line includes the second metal, and
wherein the lower voltage line includes the first metal.

5. The display device of claim 2, wherein the first linear portion of the lower voltage line and the second linear portion of the upper voltage line extend from the non-display area to the display area without overlapping each other, and
wherein the first linear portion of the lower voltage line and the second linear portion of the upper voltage line overlap each other in a region adjacent to the display area.

6. The display device of claim 5, further comprising:
a thin-film transistor disposed on the first insulating layer and including a drain electrode and a source electrode, wherein the thin-film transistor is electrically connected to the pixel electrode;
a shield pattern disposed below the thin-film transistor and including a first metal; and
a connection electrode disposed between the thin-film transistor and the pixel electrode, electrically connected to the thin-film transistor and the pixel electrode, and including a second metal,
wherein the first linear portion of the lower voltage line comprises:
a first section that does not overlap the second linear portion and includes the metal included in the drain electrode and the source electrode; and
a second section that overlaps the second linear portion and includes the first metal, and
wherein the second linear portion of the upper voltage line comprises:
a third section that does not overlap the first linear portion and includes the metal included in the drain electrode and the source electrode; and
a fourth section that overlaps the first linear portion and includes the second metal.

7. The display device of claim 1, further comprising:
a thin-film transistor disposed on the first insulating layer and including an active layer,
wherein the thin-film transistor is electrically connected to the pixel electrode, and
wherein the lower voltage line overlaps the active layer from below.

8. The display device of claim 7, wherein the thin-film transistor is disposed in contact with the pixel electrode or is electrically connected to the pixel electrode through a connection electrode, and
wherein the upper voltage line includes a material included in the connection electrode.

9. The display device of claim 7, wherein the upper voltage line overlaps the active layer from above.

10. The display device of claim 1, further comprising:
a third insulating layer disposed on the substrate; and
a thin-film transistor disposed on the third insulating layer and including an active layer,
wherein the lower voltage line overlaps the active layer from above.

11. The display device of claim 10, wherein the upper voltage line overlaps the active layer from above, and
wherein a portion of the upper voltage line overlaps the lower voltage line.

12. The display device of claim 10, further comprising a shield pattern disposed between the third insulating layer and the active layer and overlapping the active layer.

13. The display device of claim 1, wherein a vertically extending portion of the first mesh pattern overlaps a vertically extending portion of the second mesh pattern, and a horizontally extending portion of the first mesh pattern overlaps a horizontally extending portion of the second mesh pattern.

14. The display device of claim 13, further comprising:
a third insulating layer disposed on the substrate;
a thin-film transistor disposed on the third insulating layer and including an active layer; and
a shield pattern disposed between the third insulating layer and the active layer and overlapping the active layer,
wherein the lower voltage line includes a material included in the shield pattern.

15. The display device of claim 1, further comprising a thin-film transistor disposed on the first insulating layer and including an active layer,
wherein the upper voltage line comprises:
a first upper voltage line portion disposed on the thin-film transistor and overlapping the active layer; and
a second upper voltage line portion disposed on the first upper voltage line portion and electrically connected to the first upper voltage line portion.

16. The display device of claim 15, wherein the first upper voltage line portion of the upper voltage line extends in a first direction, and the second upper voltage line portion of the upper voltage line extends in a second direction intersecting the first direction.

17. The display device of claim 15, wherein the lower voltage line overlaps the active layer from below.

18. The display device of claim 1, further comprising a thin-film transistor disposed on the first insulating layer and including an active layer,
wherein the upper voltage line comprised the portion arranged in the plate pattern in the display area,
wherein the plate pattern includes a plurality of hole areas, and
wherein the pixel electrode is electrically connected to the thin-film transistor through one of the plurality of hole areas of the plate pattern.

19. The display device of claim 18, wherein the lower voltage line overlaps the active layer from below.

20. The display device of claim 1, wherein the non-display area comprises:
a first non-display area adjacent to a first side of the display area;
a second non-display area adjacent to a second side of the display area;
a third non-display area adjacent to a third side of the display area; and
a fourth non-display area adjacent to a fourth side of the display area,
wherein the upper voltage line is disposed in the first non-display area and is not disposed in the second, third, or fourth non-display area.
